(19) United States
(12) Patent Application Publication
(10) Pub. No.: US 2026/0107453 A1
(43) Pub. Date: Apr. 16, 2026

(54) SEMICONDUCTOR DEVICE AND MANUFACTURING METHOD THEREOF

(71) Applicant: Samsung Electronics Co., Ltd., Suwon-si (KR)

(72) Inventors: Munwoo Lee, Suwon-si (KR); JUNHYEOK AHN, Suwon-si (KR)

(21) Appl. No.: 19/251,566

(22) Filed: Jun. 26, 2025

(30) Foreign Application Priority Data
Oct. 11, 2024 (KR) 10-2024-0138511

(51) Int. Cl. H10B 12/00

(52) U.S. Cl. CPC H10B 12/50; H10B 12/09

(57) ABSTRACT

The present disclosure relates to a semiconductor device and a manufacturing method therefor. An embodiment of the present disclosure provides a semiconductor device including: a substrate including a cell region and a peripheral circuit region; an insulating layer within an element separation trench defining active regions of the substrate; a gate electrode crossing the active regions; and a gate insulating layer between the active regions and the gate electrode, wherein the element separation trench includes a boundary trench part positioned in a boundary region which is adjacent to boundaries of the cell region and the peripheral circuit region, the insulating layer includes a first insulating layer covering sidewalls and a bottom surface of the boundary trench part, a second insulating layer formed on the first insulating layer and covering a portion of an inner surface of the first insulating layer in the peripheral circuit region, a third insulating layer on the second insulating layer and covering an inner surface of the second insulating layer, and a fourth insulating layer on an upper surface of a first end portion of the second insulating layer. The second insulating layer is positioned between the first insulating layer and the third insulating layer in the boundary region, and a lower surface of the fourth insulating layer is positioned at a level lower than that of an upper surface of the gate electrode.

### CROSS-REFERENCE TO RELATED APPLICATION

This application claims priority to and the benefit of Korean Patent Application No. 10-2024-0138511, filed in the Korean Intellectual Property Office on Oct. 11, 2024, the entire contents of which are incorporated herein by reference.

### BACKGROUND

### 1. Field

The present disclosure relates to a semiconductor device and a manufacturing method therefor.

### 2. Description of the Related Art

In order to reduce effects of shortened channel lengths and leakage currents due to high integration of semiconductor devices, a buried channel array transistor (BCAT) has been proposed in which a gate electrode is buried inside a semiconductor substrate and an overlapping portion of gate and drain regions is minimized.

### SUMMARY

Embodiments attempt to provide a semiconductor device and a manufacturing method therefor, capable of ameliorating defects in a gate electrode and improving electrical characteristics. However, the objectives and advantages of the present invention are not limited thereto.

An embodiment of the present disclosure provides a semiconductor device including: a substrate including a cell region and a peripheral circuit region; an insulating layer within an element separation trench defining active regions of the substrate; a gate electrode crossing the active regions; and a gate insulating layer between the active regions and the gate electrode, wherein the element separation trench includes a boundary trench part positioned in a boundary region which is adjacent to boundaries of the cell region and the peripheral circuit region, the insulating layer includes a first insulating layer covering sidewalls and a bottom surface of the boundary trench part, a second insulating layer formed on the first insulating layer and covering a portion of an inner surface of the first insulating layer in the boundary trench part, a third insulating layer formed on the second insulating layer and covering an inner surface of the second insulating layer, and a fourth insulating layer on an upper surface of a first end portion of the second insulating layer. The second insulating layer is positioned between the first insulating layer and the third insulating layer in the boundary region, and a lower surface of the fourth insulating layer is positioned at a level lower than that of an upper surface of the gate electrode.

An embodiment of the present disclosure provides a semiconductor device including: a substrate including a cell region and a peripheral circuit region; an insulating layer within an element separation trench defining active regions of the substrate; a gate electrode crossing the active regions; and a gate insulating layer between the active regions and the gate electrode, wherein the element separation trench includes a boundary trench part positioned at a boundary between the cell region and the peripheral circuit region, the insulating layer within the boundary trench part includes a first insulating layer covering sidewalls and a bottom surface of the boundary trench part, a second insulating layer on the first insulating layer and covering a portion of an inner surface of the first insulating layer in the peripheral circuit region, a third insulating layer on the second insulating layer and covering an inner surface of the second insulating layer, and a fourth insulating layer on an upper surface of an end portion of the second insulating layer. The second insulating layer is positioned between the first insulating layer and the third insulating layer in the peripheral circuit region, and a boundary surface between the fourth insulating layer and the second insulating layer is positioned at a lower level than an upper surface of the gate electrode.

An embodiment of the present disclosure provides a manufacturing method for a semiconductor device, including: sequentially forming a first insulating material layer and a second insulating material layer to conformally cover a sidewall and a bottom surface of a boundary trench part of an element separation trench. The boundary trench part is positioned in a boundary region between a cell region and a peripheral circuit region of a substrate. The first insulating material layer and the second insulating material layer fill a first space within the boundary trench part. The manufacturing method further include forming a third insulating material layer to fill a second space of the boundary trench part; forming a recess by partially removing the second insulating material layer, wherein the recess has sides exposing the first insulating material layer and the third insulating material layer and a bottom by exposing the second insulating material layer; forming a fourth insulating material layer to fill the recess; forming a gate trench that crosses active regions of the cell region and extends to a boundary between the cell region and the peripheral circuit region; and forming a gate electrode within the gate trench, wherein the gate electrode partially cover the first to fourth insulating material layers within the above boundary trench part, and after the forming of the fourth insulating material layer, a lower surface of the fourth insulating layer material positioned in the peripheral circuit region within the boundary trench part is positioned at a lower level than that of an upper surface of the gate electrode.

According to example embodiments, a semiconductor device includes a substrate including a cell region and a peripheral circuit region, an insulating layer within an element separation trench defining active regions of the substrate, a gate electrode crossing the active regions, and gate insulating layer between the active regions and the gate electrode. The element separation trench includes a boundary trench part positioned in a boundary region which is adjacent to boundaries of the cell region and the peripheral circuit region. In the boundary region, the insulating layer includes a first insulating part filling the boundary trench part, and a second insulating part which is surrounded by the first insulating part layer. The second insulating part has a nitrogen concentration greater than that of the first insulating part. The second insulating part has a conformal shape along a profile of the boundary trench part. The second insulating part has first and second end portions, which are positioned along opposite sidewalls of the boundary trench part, and the second end portion is positioned closer to a center of the cell region than the first end portion. The upper surfaces of both of the first and second end portions are positioned at a lower level than upper surfaces of the active regions.

According to embodiments, it may be possible to ameliorate defects in a gate electrode and improve electrical characteristics

### BRIEF DESCRIPTION OF THE DRAWINGS

The above and other aspects, features, and advantages of the present inventive concept will be more clearly understood from the following detailed description, taken in conjunction with the accompanying drawings.

FIG. 1 illustrates a schematic top plan view of a semiconductor device according to an embodiment.

FIG. 2 illustrates an enlarged view of a region P1 in FIG. 1.

FIG. 3 illustrates an enlarged view of a region P2 in FIG. 1.

FIG. 4 illustrates a cross-sectional view taken along a line A-A′ of FIG. 2.

FIG. 5 illustrates an enlarged view of a region P11 in FIG. 4.

FIG. 6 illustrates a cross-sectional view taken along lines B-B′, C-C′, and D-D′ of FIG. 3.

FIG. 7 illustrates an enlarged view of a cross-section taken along a line D-D′ of FIG. 6.

FIG. 8 and FIG. 9 each illustrate a cross-sectional view showing a semiconductor device according to a comparative embodiment.

FIG. 10 illustrates an enlarged view of a cross-section taken along a line D-D′ of FIG. 9.

FIG. 11 illustrates a cross-sectional view of a semiconductor device according to an embodiment.

FIG. 12 illustrates an enlarged view of a region P12 in FIG. 11.

FIG. 13 illustrates a cross-sectional view of a semiconductor device according to an embodiment.

FIG. 14 illustrates an enlarged view of a region P13 in FIG. 13.

FIG. 15 to FIG. 20 are cross-sectional views showing a manufacturing method of a semiconductor device according to an embodiment.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present invention.

To clearly describe the present invention, the detailed explanation and illustrations of known functions or components may be omitted to avoid obscuring the core aspects of the invention, and like numerals refer to like or similar components throughout the specification.

Further, since sizes and thicknesses of constituent members shown in the accompanying drawings are arbitrarily given for better understanding and ease of description, the present invention is not limited to the illustrated sizes and thicknesses. In the drawings, the thicknesses of layers, films, panels, regions, etc., may be exaggerated for clearer understanding of the description.

It will be understood that when an element such as a layer, film, region, or substrate is referred to as being “on” another element, it can be directly on the other element or intervening elements may exist therebetween. In contrast, when an element is referred to as being “directly on” or “in contact with” another element, there are no intervening elements therebetween. Further, in the specification, the word “on” or “above” may refer to being positioned on or below the object, and does not necessarily mean positioning on the upper side of the object according to the direction of gravity.

In addition, unless explicitly described to the contrary, the word “comprise” and variations such as “comprises” or “comprising” will be understood to imply the inclusion of stated elements but not the exclusion of any other elements. When a component is described as “including” a particular element or group of elements, it is to be understood that the component is formed of only the element or the group of elements, or the element or group of elements may be combined with additional elements to form the component, unless the context indicates otherwise.

Items described in the singular herein may be provided in plural, as can be seen, for example, in the drawings. Thus, the description of a single item that is provided in plural should be understood to be applicable to the remaining plurality of items unless context indicates otherwise.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Further, throughout the specification, the phrase “in a plan view” means when an object is viewed from above, and the phrase “in a cross-sectional view” means when a cross-section of the object, taken by a vertical cut, is viewed from the side.

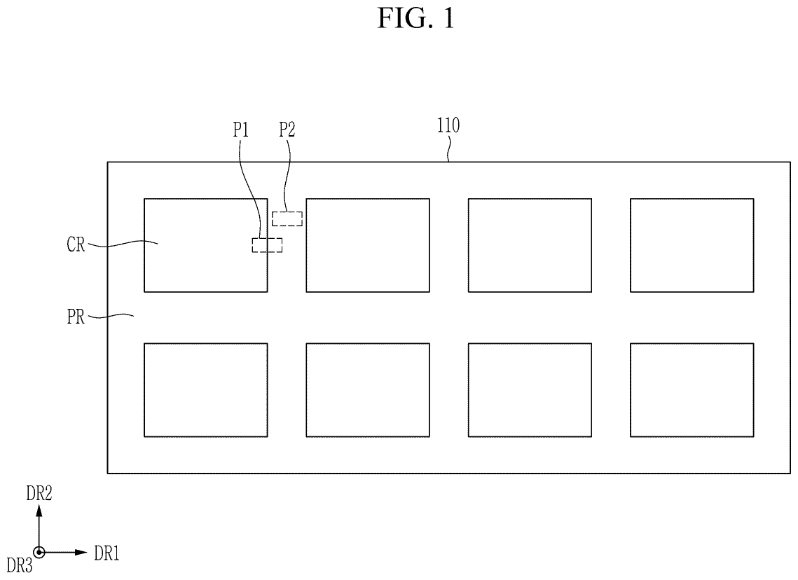

Hereinafter, a semiconductor device according to an embodiment will be described with reference to FIG. 1 to FIG. 7.

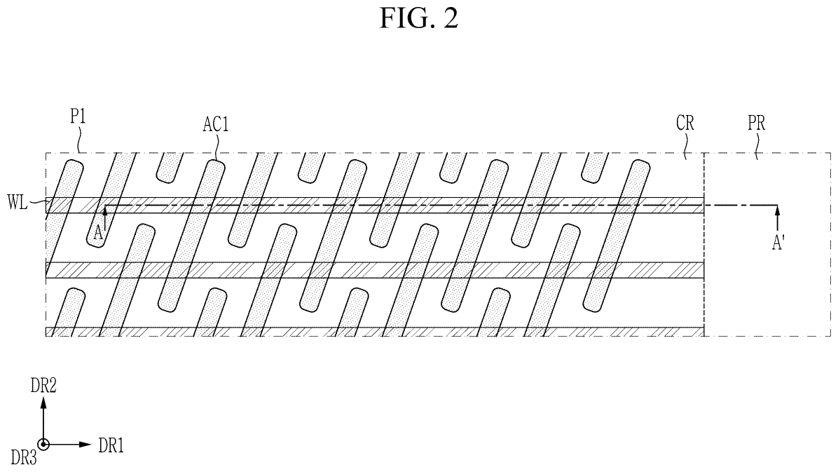

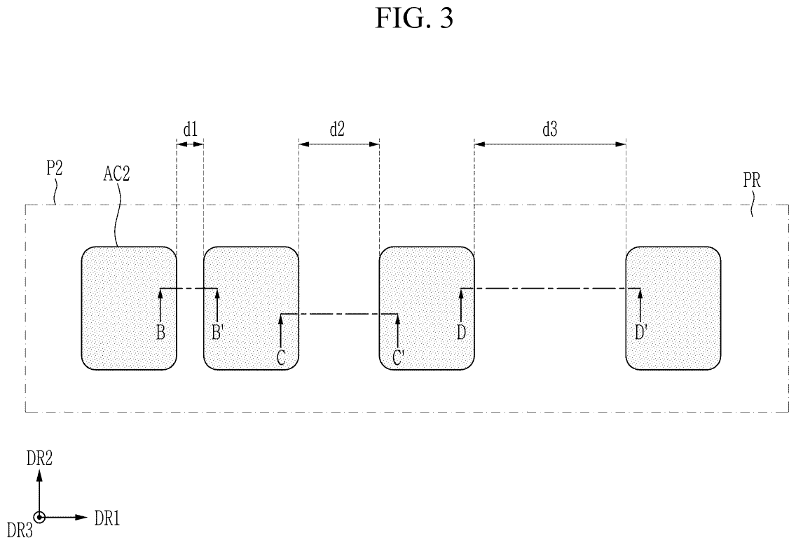

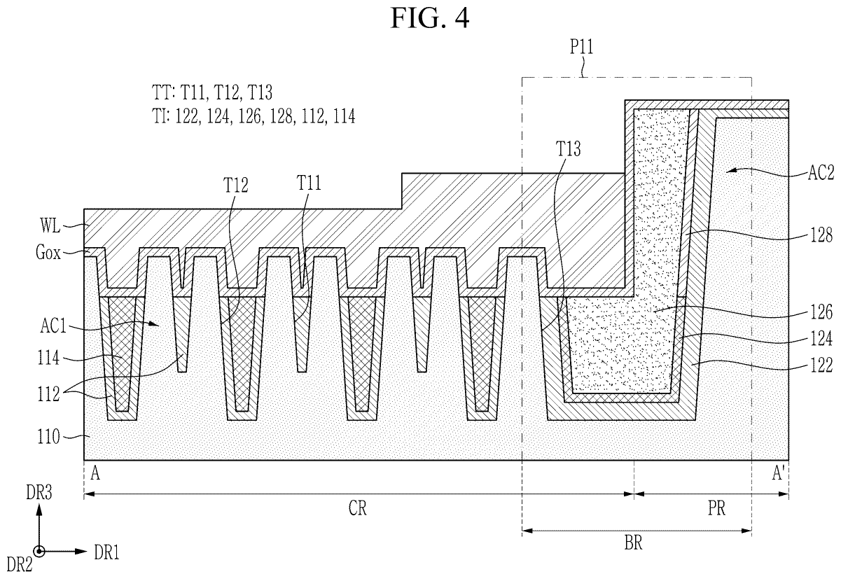

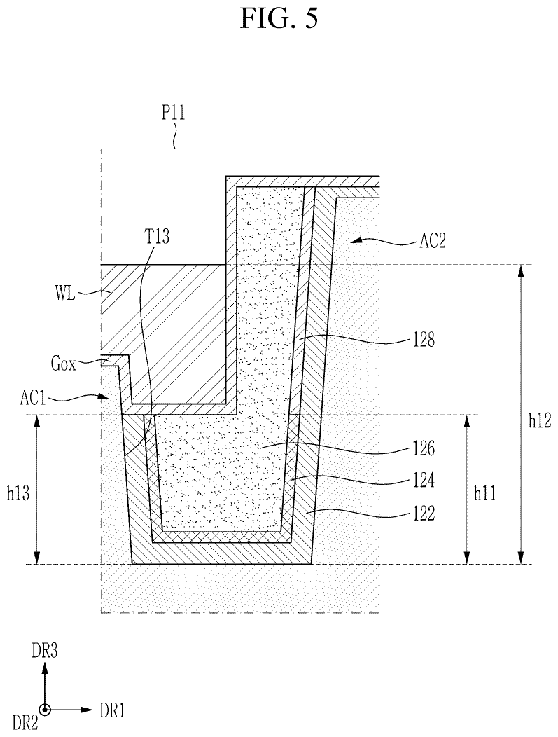

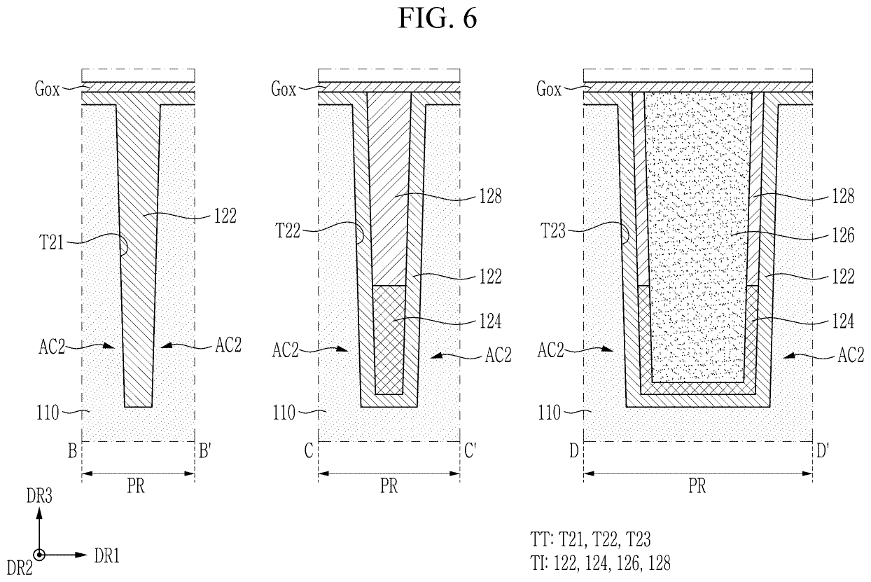

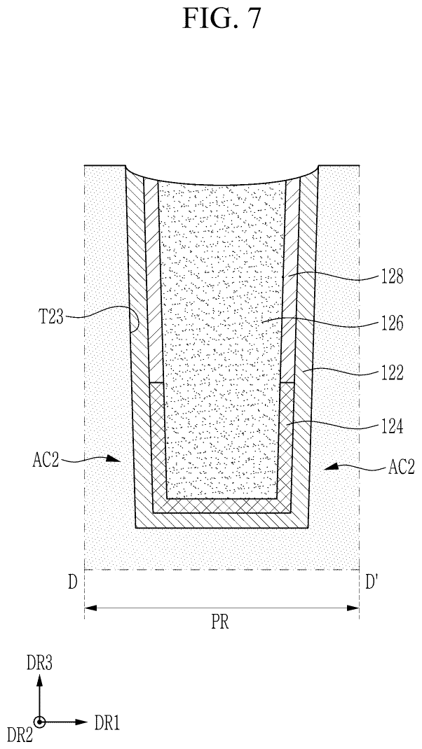

FIG. 1 illustrates a schematic top plan view of a semiconductor device according to an embodiment. FIG. 2 illustrates an enlarged view of a region P1 in FIG. 1. FIG. 3 illustrates an enlarged view of a region P2 in FIG. 1. FIG. 4 illustrates a cross-sectional view taken along a line A-A′ of FIG. 2. FIG. 5 illustrates an enlarged view of a region P11 in FIG. 4. FIG. 6 illustrates a cross-sectional view taken along lines B-B′, C-C′, and D-D′ of FIG. 3. FIG. 7 illustrates an enlarged view of a cross-section taken along a line D-D′ of FIG. 6. FIG. 7 illustrates a state in which some components of FIG. 6 have been removed in a subsequent process.

FIG. 4 to FIG. 7 may represent an example structure of an intermediate state in a process of forming a semiconductor device. A semiconductor device illustrated in FIGS. 4 to 7 is illustrated by focusing on a device isolation structure, and the semiconductor device may further include other components in addition to the components illustrated in FIGS. 4 to 7 through subsequent processes. For example, bit lines, capacitors, etc. may be further included in the semiconductor device.

Although the present invention may be described with reference to drawings illustrating an example structure of an intermediate state, the invention is not limited to this specific example structure. Those skilled in the art will understand that various modifications of the present invention, including semiconductor devices incorporating the described features as well as semiconductor devices fabricated using the intermediate state structure, are within the scope of the present disclosure and do not depart from its spirit or scope.

First, referring to FIG. 1, the semiconductor device may include a substrate 110. The substrate 110 may include a cell region CR and a peripheral circuit region PR. The substrate 110 may include, e.g., a semiconductor material such as silicon, germanium, or silicon-germanium, or a group III-V compound such as GaP, GaAs, or GaSb. The substrate 110 may be, e.g., a silicon on insulator (SOI) substrate or a germanium on insulator (GOI) substrate.

The cell region CR may be a region where memory cells are formed. For example, the memory cells may be arranged in an array form in the cell region CR. The substrate 110 may include a plurality of cell regions CR, and the cell regions CR may be spaced apart and arranged along a first direction DR1 parallel to an upper (and/or lower) surface of the substrate 110 and a second direction DR2 intersecting the first direction DR1. For example, the second direction DR2 may be perpendicular to the first direction DR1. Although eight cell regions CR are shown in FIG. 1, this is only an example, and a number of cell regions CR may vary.

The peripheral circuit region PR may be a region where peripheral circuit elements that drive memory cells are formed. The peripheral circuits may perform various functions for the operation of the semiconductor device. For example, the peripheral circuits may include row/column decoder, sensing/amplifier, data input/output buffer, etc. The peripheral circuit region PR may be positioned around the cell region CR. The peripheral circuit region PR may surround the cell region CR. The peripheral circuit region PR may be positioned between the cell regions CR spaced apart in the first direction DR1 and the second direction DR2.

A region P1 of FIG. 1 may include a boundary region between the cell region CR and the peripheral circuit region PR, and a region P2 of FIG. 2 may be a portion of the peripheral circuit region PR. The boundary region (BR in FIG. 4) may be close to the boundaries of the cell region CR and the peripheral circuit region PR. The boundary region may partially overlap with the cell region CR and the peripheral circuit region PR.

Referring to FIGS. 2 and 3, a plurality of first active regions AC1 may be positioned in the cell region CR. For example, the first active region AC1 may have a bar shape extending in a direction intersecting the first direction DR1 and the second direction DR2. The first active regions AC1 may be spaced and arranged along the first direction DR1 and the second direction DR2. The first active regions AC1 adjacent to each other along the first direction DR1 may be arranged such that their centers are misaligned. The first active regions AC1 adjacent to each other along the second direction DR2 may be arranged such that a first end portion of one of them and a second end portion of the other are adjacent to each other in the first direction DR1.

A gate electrode WL extending in the first direction DR1 across the first active region AC1 may be positioned in the cell region CR. The gate electrode WL may extend to a boundary between the cell region CR and the peripheral circuit region PR. A plurality of gate electrodes WL may be positioned in the cell region CR, and the gate electrodes WL may be arranged and spaced apart in the second direction DR2. Each of the first active regions AC1 may intersect two gate electrodes WL. A center of the first active region AC1 may be positioned between two gate electrodes WL. The gate electrode WL may alternatively be referred to as a word line.

A plurality of second active regions AC2 may be positioned in the peripheral circuit region PR. In FIG. 3, a planar shape (a shape viewed from a vertical direction, e.g., a third direction DR3) of the second active region AC2 is illustrated as a square with rounded corners, but the present invention is not limited thereto. The planar shape of the second active region AC2 may be changed in various ways. The second active regions AC2 may be arranged to be spaced apart from each other, and in FIG. 3, and the second active regions AC2 are illustrated as being arranged to be spaced apart along the first direction DR1, but the present invention is not limited thereto.

The first active region AC1 and the second active region AC2 may be defined by an element separation trench TT. The element separation trench TT may be positioned between the first active regions AC1, between the second active regions AC2, and between the first active region AC1 and the second active region AC2. The element separation trench TT may include a first cell trench T11 and a second cell trench T12, which are positioned between the first active regions AC1. The element separation trench TT may further include a boundary trench T13 positioned between the first active region AC1 and the second active region AC2. The element separation trench TT may further include a first peripheral circuit trench T21, a second peripheral circuit trench T22, and a third peripheral circuit trench T23, which are positioned between the second active regions AC2. Each of the trenches T11, T12, T13, T21, T22 and T23 may be interconnected to form a single trench TT (although not shown in the cross section). The first active region AC1 and the second active region AC2 may be formed in (as part of) the substrate 101. Accordingly, the substrate 101 may not necessarily require materially distinctiveness from the active regions. The first cell trench T11, the second cell trench T12, the boundary trench T13, the first peripheral circuit trench T21, the second peripheral circuit trench T22, and the third peripheral circuit trench T23 may also be referred to as the first cell trench part T11, the second cell trench part T12, the boundary trench part T13, the first peripheral circuit trench part T21, the second peripheral circuit trench part T22, and the third peripheral circuit trench part T23, respectively.

According to an embodiment, the first cell trench T11 and the second cell trench T12 may be positioned in the cell region CR. The boundary trench T13 may be positioned at a boundary region BR between the cell region R and the peripheral circuit region PR. The first peripheral circuit trench T21, the second peripheral circuit trench T22, and the third peripheral circuit trench T23 may be positioned in the peripheral circuit region PR.

A width of the element separation trenches may vary depending on a distance by which the active regions are separated. A distance between the first active regions AC1 separated by the first cell trench T11 may correspond to a width of the first cell trench T11. The distance between the first active regions AC1 separated by the second cell trench T12 may correspond to a width of the second cell trench T12. A distance between the first active region AC1 and the second active region AC2, which are separated by the boundary trench T13, may correspond to a width of the boundary trench T13. According to an embodiment, a width of the boundary trench T13 may be greater than a width of the first cell trench T11 and a width of the second cell trench T12. The width of the second cell trench T12 may be greater than the width of the first cell trench T11.

A distance d1 between the second active regions AC2 separated by the first peripheral circuit trench T21 may correspond to the width of the first peripheral circuit trench T21. A distance d2 between the second active regions AC2 separated by the second peripheral circuit trench T22 may correspond to the width of the second peripheral circuit trench T22. A distance d3 between the second active regions AC2 separated by the third peripheral circuit trench T23 may correspond to the width of the third peripheral circuit trench T23. According to an embodiment, the width of the third peripheral circuit trench T23 may be greater than the width of the first peripheral circuit trench T21 and the width of the second peripheral circuit trench T22. The width of the second peripheral circuit trench T22 may be greater than the width of the first peripheral circuit trench T21.

An insulating layer TI may be positioned within the element separation trench TT. The insulating layer TI may include a first insulating layer 122, a second insulating layer 124, a third insulating layer 126, a fourth insulating layer 128, a fifth insulating layer 112, and a sixth insulating layer 114.

Referring to FIGS. 4 and 5, the substrate 110 may include a first active region AC1 and a second active region AC2. The first active region AC1 may be positioned in the cell region CR of the substrate 110, and the second active region AC2 may be positioned in the peripheral circuit region PR of the substrate 110. Each of the first active region AC1 and the second active region AC2 may have a fin shape protruding in a third direction DR3 perpendicular to an upper surface (and/or lower) of the substrate 110. An upper surface of the first active region AC1 may be positioned at a lower level (or a lower height level) than an upper surface of the second active region AC2.

Throughout the specification, level comparisons such as “an item is at a lower level than another item” may be the comparison of heights with respect to the third direction DR3 (e.g., perpendicular to the upper and/or lower surface of the substrate).

The boundary trench T13 may be positioned between the first active region AC1 and the second active region AC2. For example, the boundary trench T13 may be positioned in the boundary region BR. A first sidewall of the boundary trench T13 may be positioned closer to a center of the cell region than a second sidewall of the boundary trench T13. A height of the first sidewall of the boundary trench T13 may be less than that of the second sidewall of the boundary trench T13. The first insulating layer 122, the second insulating layer 124, the third insulating layer 126, and the fourth insulating layer 128 may be positioned within the boundary trench T13. The outer surface of the second insulating layer 124 may be surrounded by the first insulating layer 122.

The first insulating layer 122 may cover sidewalls and a bottom surface of the boundary trench T13. The first insulating layer 122 may cover a portion of the first sidewall of the boundary trench T13, the entire bottom surface of the boundary trench T13, and the entire second sidewall of the boundary trench T13. For example, the first insulating layer 122 may not cover an upper portion of the first sidewall of the boundary trench T13 and another portion of the first sidewall adjacent thereto. An upper surface of an end portion of the first insulating layer 122 positioned in the cell region CR may be positioned at a lower level than an upper surface of the first active region AC1. The first insulating layer 122 may cover an upper surface of the second active region AC2. However, the invention is not limited thereto. For example, in some embodiments, the first insulating layer 122 may not cover the upper surface of the second active region AC2 (as illustrated in FIG. 7). The first insulating layer 122 may have a conformal shape along a profile of an inner surface of the boundary trench T13.

The first insulating layer 122 may include an insulating material. The first insulating layer 122 may include, e.g., a silicon oxide, but the present invention is not limited thereto. The material of the first insulating layer 122 may be changed in various ways.

The second insulating layer 124 may be positioned on the first insulating layer 122. The second insulating layer 124 may cover an inner surface of the first insulating layer 122. The second insulating layer 124 may have a conformal shape along a profile of an inner surface of the first insulating layer 122. In an embodiment, the second insulating layer 124 may cover a portion of the inner surface of the first insulating layer 122 in the peripheral circuit region PR. In an embodiment, the second insulating layer 124 may cover the entire inner surface of the first insulating layer 122 in the cell region CR, but the present invention is not necessarily limited thereto. According to an embodiment, the second insulating layer 124 may cover a portion of the inner surface of the first insulating layer 122 in the cell region CR. In the cell region CR, an upper surface of an end portion of the second insulating layer 124 may be positioned at substantially the same level as that of an upper surface of an end portion of the first insulating layer 122. In the peripheral circuit region PR, the upper surface of the end portion of the second insulating layer 124 may be positioned at a lower level than that of an upper surface of the second active area AC2. The upper surface of the end portion of the second insulating layer 124 positioned in the cell region CR and the upper surface of the end portion of the second insulating layer 124 positioned in the peripheral circuit region PR may be positioned at substantially the same level.

Terms such as “same,” “equal,” “constant,” “flat,” etc. as used herein, are intended to encompass meanings that include typical variations resulting from conventional manufacturing processes and/or accommodate tolerances acceptable in the manufacturing process of the semiconductor device, unless the context or other statements indicate otherwise. For example, ‘same’ and ‘equal’ may encompass identicality or near identicality.

According to an embodiment, the second insulating layer 124 may include an insulating material having a different etching selectivity from that of the first insulating layer 122. For example, the second insulating layer 124 may include a silicon nitride, but the present invention is not limited thereto. For example, in the semiconductor device, the nitrogen concentration of the second insulating layer may be greater than that of the first, third and fourth insulating layers.

The third insulating layer 126 may be positioned on the second insulating layer 124. The third insulating layer 126 may cover an inner surface of the second insulating layer 124. A lower portion of the third insulating layer 126 may be surrounded by the second insulating layer 124. The third insulating layer 126 may have a step between the cell region CR and the peripheral circuit region PR. An upper surface of the third insulating layer 126 positioned in the peripheral circuit region PR may be positioned at a higher level than that of an upper surface of the third insulating layer 126 positioned in the cell region CR. In the cell region CR, the upper surface of the third insulating layer 126 may be positioned at substantially the same level as that of the upper surface of the end portion of the first insulating layer 122. In the peripheral circuit region PR, the upper surface of the third insulating layer 126 may be positioned at substantially the same level as the upper surface of the first insulating layer 122 covering the upper surface of the second active region AC2.

The third insulating layer 126 may be separated from the first insulating layer 122 by the second insulating layer 124 and the fourth insulating layer 128, as described later. The second insulating layer 124 and the fourth insulating layer 128 may be positioned between the first insulating layer 122 and the third insulating layer 126.

The third insulating layer 126 may include an insulating material having a good gap-fill characteristic. According to an embodiment, the third insulating layer 126 may include an insulating material having a low etching selectivity for the first insulating layer 122. For example, the third insulating layer 126 may include an insulating material having a lower etch-rete than the first insulating layer 122 with respect to an etching condition. For example, the third insulating layer 126 may include tonene silazene (TOSZ), but the present invention is not limited thereto.

The fourth insulating layer 128 may be positioned between the first insulating layer 122 and the third insulating layer 126. According to an embodiment, the fourth insulating layer 128 may be positioned on an upper surface of an end portion of the second insulating layer 124. The fourth insulating layer 128 may be positioned on the upper surface of the end portion of the second insulating layer 124 positioned in the peripheral circuit region PR. In an embodiment, the fourth insulating layer 128 may not be positioned on the upper surface of the end portion of the second insulating layer 124, which is positioned in the cell region CR, but the present invention is not limited thereto. According to an embodiment, the fourth insulating layer 128 may also be positioned on the upper surface of the end portion of the second insulating layer 124 positioned in the cell region CR. An upper surface of the fourth insulating layer 128 may be positioned at substantially the same level as that of the upper surface of the third insulating layer 126 positioned in the peripheral circuit region PR. The upper surface of the fourth insulating layer 128 may be positioned at substantially the same level as the upper surface of the first insulating layer 122 positioned on the upper surface of the second active region AC2.

According to an embodiment, a lower surface of the fourth insulating layer 128 may contact the upper surface of the end portion of the second insulating layer 124 positioned in the peripheral circuit region PR. The lower surface of the fourth insulating layer 128 and the upper surface of the end portion of the second insulating layer 124 may be referred to as a boundary surface between the fourth insulating layer 128 and the second insulating layer 124. The lower surface of the fourth insulating layer 128 may be positioned at substantially the same level as those of the upper surface of the end portion of the first insulating layer 122, the upper surface of the end of the second insulating layer 124, and the upper surface of the third insulating layer 126 positioned in the cell region CR.

According to an embodiment, the fourth insulating layer 128 may include an insulating material having a low etching selectivity for the first insulating layer 122 and the third insulating layer 126. For example, the fourth insulating layer 128 may include the same material as that of the first insulating layer 122 or the third insulating layer 126, but the present invention is not limited thereto. As an example, the fourth insulating layer 128 may include a silicon oxide. In an embodiment, the fourth insulating layer 128 may have an etching rate substantially the same as those of the first insulating layer 122 and the third insulating layer 126 with respect to an etching condition.

In an embodiment, etch selectivity of the fourth insulating layer 128 with respect to the first insulating layer 122 and the third insulating layer 126 may be lower than etch selectivity of the second insulating layer 124 with respect to the first insulating layer 122 and the third insulating layer 126. For example, under the same etching condition (e.g., when the same etchant is used), a difference between an etch-rate of the fourth insulating layer 128 and etch-rates of the first insulating layer 122 and the third insulating layer 126 may be smaller than a difference between an etch-rate of the second insulating layer 124 and the etch-rates of the first insulating layer 122 and the third insulating layer 126.

A first cell trench T11 and a second cell trench T12 may be positioned between the first active regions AC1. The fifth insulating layer 112 may be positioned inside the first cell trench T11, and the fifth insulating layer 112 and the sixth insulating layer 114 may be positioned inside the second cell trench T12.

A width of the first cell trench T11 and a width of the second cell trench T12 may be smaller than a width of the boundary trench T13. The width of the second cell trench T12 may be greater than the width of the first cell trench T11. A depth of the second cell trench T12 may be deeper than a depth of the first cell trench T11. For example, a width of the element separation trench TT may indicate a length along the first direction DR1 between opposite sidewalls of the element separation trench TT. A depth of the element separation trench TT may indicate a length along the third direction DR3 from a lower surface (or lower portion) to an upper surface (or upper portion) of the element separation trench TT. Throughout the specification, width comparison between trench parts may be based on values measured in a plane which is parallel to an upper surface (and/or lower) of the substrate, unless the context indicates otherwise. For example, the plane may be a plane extending in the first direction DR1 and the second direction DR2, and the widths may be measured in the same direction within this plane.

The fifth insulating layer 112 may cover sidewalls and a bottom surface of the first cell trench T11. The fifth insulating layer 112 may cover portions of the opposite sidewalls of the first cell trench T11 and the entire bottom surface of the first cell trench T11. For example, the fifth insulating layer 112 may not cover upper portions of the opposite sidewalls of the first cell trench T11 and other portions of the sidewalls adjacent thereto. The fifth insulating layer 112 may be positioned at a level that is lower than that of the upper surface of the first active region AC1.

The fifth insulating layer 112 may cover sidewalls and a bottom surface of the second cell trench T12. The fifth insulating layer 112 may cover portions of the opposite sidewalls of the second cell trench T12 and the entire bottom surface of the second cell trench T12. For example, the fifth insulating layer 112 may not cover upper portions of the opposite sidewalls of the second cell trench T12 and other portions of the sidewalls adjacent thereto. The fifth insulating layer 112 may have a conformal shape along a profile of an inner surface of the second cell trench T12. An upper surface of an end portion of the fifth insulating layer 112 may be positioned at a level that is lower than that of the upper surface of the first active region AC1.

The fifth insulating layer 112 may include an insulating material. The fifth insulating layer 112 may include, e.g., a silicon oxide, but the present invention is not limited thereto. A material of the first insulating layer 122 may be changed in various ways.

The sixth insulating layer 114 may be positioned within the second cell trench T12, and may not be positioned within the first cell trench T11. The first cell trench T11 having a relatively narrow width may be filled with the fifth insulating layer 112. For example, the fifth insulating layer 112 may completely fill the first cell trench T11. The sixth insulating layer 114 may be positioned on the fifth insulating layer 112 within the second cell trench T12. The sixth insulating layer 114 may cover an inner surface of the fifth insulating layer 112. An upper surface of the sixth insulating layer 114 may be positioned at substantially the same level as that of an upper surface of an end portion of the fifth insulating layer 112.

The sixth insulating layer 114 may include an insulating material having a different etching selectivity from that of the fifth insulating layer 112. For example, the sixth insulating layer 114 may include a silicon nitride, but the present invention is not limited thereto. For example, a nitrogen concentration of the sixth insulating layer may be greater than that of the fifth insulating layer.

An upper surface of the insulating layer TI positioned within the first cell trench T11 and the second cell trench T12 may be positioned at substantially the same level as that of an upper surface of the insulating layer TI positioned within the cell region CR within the boundary trench T13.

A gate insulating layer Gox may be positioned in both the cell region CR and the peripheral circuit region PR. The gate electrode WL may be positioned in the cell region CR, and may not be positioned in the peripheral circuit region PR. The gate electrode WL may be positioned on the gate insulating layer Gox.

The gate electrode WL may extend in the first direction DR1 across the first active region AC1 in the cell region CR. The gate electrode WL may surround the upper portion of the first active region AC1. The gate electrode WL may be positioned inside the first cell trench T11, the second cell trench T12, and the boundary trench T13. The gate electrode WL may be positioned at upper portions of the first cell trench T11, the second cell trench T12, and the boundary trench T13.

The gate electrode WL may cover an upper surface of the fifth insulating layer 112 within the first cell trench T11. The gate electrode WL may cover upper portions of opposite sides of the first cell trench T11. The gate electrode WL may cover an upper surface of an end portion of the fifth insulating layer 112 and an upper surface of the sixth insulating layer 114 within the second cell trench T12. The gate electrode WL may cover upper portions of opposite sides of the second cell trench T12.

The gate electrode WL may cover an upper surface of an end portion of the first insulating layer 122 positioned in the cell region CR, an upper surface of an end portion of the second insulating layer 124 positioned in the cell region CR, and an upper surface of the third insulating layer 126 positioned in the cell region CR within the boundary trench T13. The gate electrode WL may cover a side surface of the third insulating layer 126 positioned at a boundary between the cell region CR and the peripheral circuit region PR within the boundary trench T13.

An upper surface of the gate electrode WL may be positioned at a higher level than that of the upper surface of the first active region AC1. In an embodiment, the upper surface of the gate electrode WL may have a step. An upper surface of a portion of the gate electrode WL adjacent to the peripheral circuit region PR may be positioned at a higher level than that of an upper surface of another portion of the gate electrode WL that is relatively distant from the peripheral circuit region PR.

In an embodiment, a portion of the gate electrode WL adjacent to the peripheral circuit region PR may be thicker than another portion of the gate electrode WL in a direction perpendicular to the upper surface (and/or lower) of the substrate 110 (e.g., in the third direction DR3). The other portion of the gate electrode WL may indicate a part that is relatively far from the peripheral circuit region PR.

In an embodiment, a thickness of the gate electrode WL along the third direction DR3 within the boundary trench T13 may be constant. A lower surface of the gate electrode WL within the boundary trench T13 may be substantially flat. For example, within the boundary trench T13, the lower surface of the gate electrode WL may be spaced apart from the bottom surface of the boundary trench T13 at a substantially constant vertical distance. For example, within the boundary trench T13, the lower surface of the gate electrode WL may be substantially smooth (for example, without any unevenness or irregularity) and flat.

The gate electrode WL may include a conductive material. The gate electrode WL may include, e.g., doped polysilicon, a metal, or a metal compound.

The gate insulating layer Gox may be positioned between the gate electrode WL and the first active region AC1. The gate electrode WL may be separated from the first active region AC1 by the gate insulating layer Gox. The gate insulating layer Gox may be positioned between the gate electrode WL and the insulating layer TI.

The gate insulating layer Gox may conformally cover a surface of an upper portion of the first active region AC1 and a surface of the insulating layer TI. The gate insulating layer Gox may cover the upper surface and upper portions of opposite sides of the first active region AC1. The gate insulating layer Gox may cover an upper surface of the fifth insulating layer 112 within the first cell trench T11. The gate insulating layer Gox may cover an upper surface of an end portion of the fifth insulating layer 112 and an upper surface of the sixth insulating layer 114 within the second cell trench T12. The gate insulating layer Gox may cover an upper surface of an end portion of the first insulating layer 122, an upper surface of an end portion of the second insulating layer 124, and an upper surface of the third insulating layer 126 positioned in the cell region CR within the boundary trench T13. The gate insulating layer Gox may cover a side surface of the third insulating layer 126 positioned at a boundary between the cell region CR and the peripheral circuit region PR within the boundary trench T13. The gate insulating layer Gox may cover an upper surface of the third insulating layer 126, an upper surface of the fourth insulating layer 128, and an upper surface of the first insulating layer 122 positioned in the peripheral circuit region PR.

The gate insulating layer Gox may include an insulating material. The gate insulating layer Gox may include, e.g., a silicon oxide, a silicon nitride, a silicon oxynitride, or a high-k material. The high dielectric constant material may indicate a material having a higher dielectric constant than that of the silicon oxide. The high dielectric constant material may include, e.g., a hafnium oxide, an aluminum oxide, a tantalum oxide, a titanium oxide, an yttrium oxide, a zirconium oxide, a lanthanum oxide, and the like, but the present invention is not limited thereto.

According to an embodiment, a lower surface of the fourth insulating layer 128 may be positioned at a lower level than that of the upper surface of the gate electrode WL. As illustrated in FIG. 5, a height h11 from a bottom surface of the boundary trench T13 to a lower surface of the fourth insulating layer 128 may be lower (or less) than a height h12 from the bottom surface of the boundary trench T13 to the upper surface of the gate electrode WL.

According to an embodiment, the lower surface of the fourth insulating layer 128 may be positioned at substantially the same level as that of the upper surface of the end portion of the first insulating layer 122 positioned in the cell region CR. As illustrated in FIG. 5, the height h11 from the bottom surface of the boundary trench T13 to the lower surface of the fourth insulating layer 128 may be substantially equal to a height h13 from the bottom surface of the boundary trench T13 to the upper surface of the end portion of the first insulating layer 122 positioned in the cell region CR.

Referring to FIG. 6, a first peripheral circuit trench T21, a second peripheral circuit trench T22, and a third peripheral circuit trench T23 may be positioned between the second active regions AC2. As described above, a width of the second peripheral circuit trench T22 may be greater than a width of the first peripheral circuit trench T21, and a width of the third peripheral circuit trench T23 may be greater than the width of the second peripheral circuit trench T22.

The above-described first insulating layer 122 may be further positioned within the first peripheral circuit trench T21, the second peripheral circuit trench T22, and the third peripheral circuit trench T23. The above-described second insulating layer 124 may be further positioned within the second peripheral circuit trench T22 and the third peripheral circuit trench T23. The third insulating layer 126 described above may be further positioned within the third peripheral circuit trench T23. The above-described fourth insulating layer 128 may be further positioned within the second peripheral circuit trench T22 and the third peripheral circuit trench T23.

The first insulating layer 122 may cover sidewalls and a bottom surface of the first peripheral circuit trench T21. The first insulating layer 122 may cover sidewalls and a bottom surface of the second peripheral circuit trench T22. The first insulating layer 122 may cover sidewalls and a bottom surface of the third peripheral circuit trench T23. The first insulating layer 122 may also be positioned on the upper surface of the second active region AC2. The first insulating layer 122 may have a conformal shape within the second peripheral circuit trench T22 and the third peripheral circuit trench T23. The first insulating layer 122 may completely fill an internal space of the first peripheral circuit trench T21.

The second insulating layer 124 may be positioned within the second peripheral circuit trench T22 and the third peripheral circuit trench T23, but may not be positioned within the first peripheral circuit trench T21. The second insulating layer 124 may be positioned on the first insulating layer 122 within the second peripheral circuit trench T22 and the third peripheral circuit trench T23. The second insulating layer 124 may cover a portion of an inner surface of the first insulating layer 122. The second insulating layer 124 may cover an inner surface of a portion of the first insulating layer 122, which is positioned at lower portions of the second peripheral circuit trench T22 and the third peripheral circuit trench T23. The second insulating layer 124 may have a conformal shape within the third peripheral circuit trench T23. An upper surface of the second insulating layer 124 may be positioned at a level that is lower than that of the upper surface of the second active region AC2.

The third insulating layer 126 may be positioned within the third peripheral circuit trench T23, and may not be positioned within the first peripheral circuit trench T21 and the second peripheral circuit trench T22. The third insulating layer 126 may be positioned on the second insulating layer 124 within the third peripheral circuit trench T23. The third insulating layer 126 may cover an inner surface of the second insulating layer 124. The third insulating layer 126 may be in contact with the second insulating layer 124, and may be separated from the first insulating layer 122 by the second insulating layer 124 and the fourth insulating layer 128 as described below. A lower portion of the third insulating layer 126 may be surrounded by the second insulating layer 124. The upper surface of the third insulating layer 126 may be positioned at substantially the same level as the upper surface of the first insulating layer 122 covering the upper surface of the second active region AC2.

The fourth insulating layer 128 may be positioned within the second peripheral circuit trench T22 and the third peripheral circuit trench T23, but may not be positioned within the first peripheral circuit trench T21. The fourth insulating layer 128 may be positioned between portions of the first insulating layer 122 that are positioned on opposite sidewalls of the second peripheral circuit trench T22 within the second peripheral circuit trench T22. The fourth insulating layer 128 may be positioned on the upper surface of the second insulating layer 124 within the second peripheral circuit trench T22. A lower surface of the fourth insulating layer 128 may be in contact with the upper surface of the second insulating layer 124. The upper surface of the fourth insulating layer 128 may be positioned at substantially the same level as the upper surface of the first insulating layer 122 covering the upper surface of the second active region AC2.

The fourth insulating layer 128 may be positioned between the first insulating layer 122 and the third insulating layer 126 within the second peripheral circuit trench T23. The fourth insulating layer 128 may be positioned on the opposite end portions of the second insulating layer 124, and the opposite end portions may be positioned on the opposite sides of the third peripheral circuit trench T23. The fourth insulating layer 128 may be positioned on an upper surface of an end portion of the second insulating layer 124 within the second peripheral circuit trench T22. A lower surface of the fourth insulating layer 128 may be in contact with an upper surface of an end portion of the second insulating layer 124.

The gate insulating layer Gox may cover the upper surface of the first insulating layer 122 on the first peripheral circuit trench T21. The gate insulating layer Gox may cover the upper surface of the first insulating layer 122 and the upper surface of the fourth insulating layer 128 on the second peripheral circuit trench T22. The gate insulating layer Gox may cover the upper surface of the first insulating layer 122, the upper surface of the third insulating layer 126, and the upper surface of the fourth insulating layer 128 on the third peripheral circuit trench T23.

FIG. 7 illustrates a view for describing a shape of an upper surface of the insulating layer TI positioned within the third peripheral circuit trench T23 in detail. FIG. 7 illustrates a state in which a portion of the first insulating layer 122 and a portion of the gate insulating layer Gox of FIG. 6 are removed in a subsequent process. For example, in a subsequent process, the first insulating layer 122 and the gate insulating layer Gox positioned on an upper surface of the second active region AC2 may be removed. The removal process may be optionally performed (or omitted) after producing the structure described with reference to FIGS. 4 to 6. For example, FIG. 7 may illustrate a modified version of the semiconductor device, where the optional removal process is applied to the embodiment described with reference to FIGS. 4 to 6.

As described above, the fourth insulating layer 128 may include a material having a low etching selectivity for the first insulating layer 122 and the third insulating layer 126. In some embodiments, etch rates of the fourth insulating layer 128, the first insulating layer 122, and the third insulating layer 126 may have little difference or may be substantially the same as each other.

Referring to FIG. 7, an upper surface of the insulating layer TI positioned within the third peripheral circuit trench T23 may have a shape that is recessed overall toward a bottom surface of the third peripheral circuit trench T23. The upper surface of the insulating layer TI positioned within the third peripheral circuit trench T23 may be lowered closer to a central portion of the third peripheral circuit trench T23. According to an embodiment, an upper surface of an end portion of the first insulating layer 122 may be lowered toward the upper surface of the fourth insulating layer 128. It may be lowered from the upper surface of the fourth insulating layer 128 to the upper surface of the third insulating layer 126. For example, a portion extending from an upper surface of an end portion of the first insulating layer 122 to an upper surface of the fourth insulating layer 128 may form a gentle curve. A portion extending from the upper surface of the fourth insulating layer 128 to the upper surface of the third insulating layer 126 may form a gentle curve. For example, the combination of the first insulating layer 122, the third insulating layer 126 and the fourth insulating layer 128 may have a composite upper surface. The composite upper surface may have a recessed shape (or the gentle-curved shape) such that a height level of the composite upper surface decreases as the composite upper surface moves away from edges of the composite upper surface. The upper surface of the insulating layer TI positioned in the third peripheral circuit trench T23 may be gradually lowered as the upper surface of the insulating layer TI moves away from edges of the composite upper surface or away from the sidewalls of the third peripheral circuit trench T23.

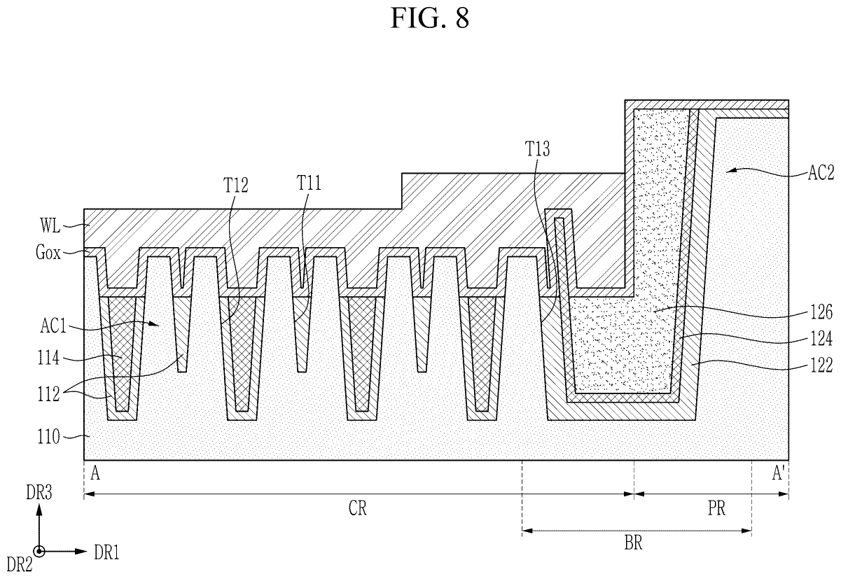

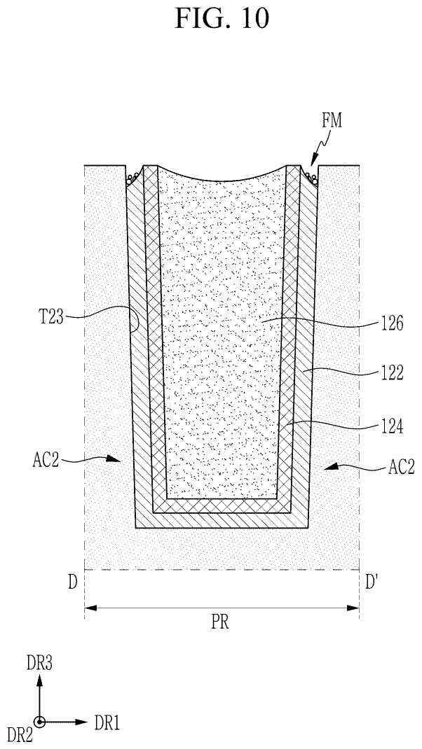

Hereinafter, a semiconductor device according to a comparative example will be described with reference to FIG. 8 and FIG. 10. It may be understood that the comparative example may fall within the scope of the invention.

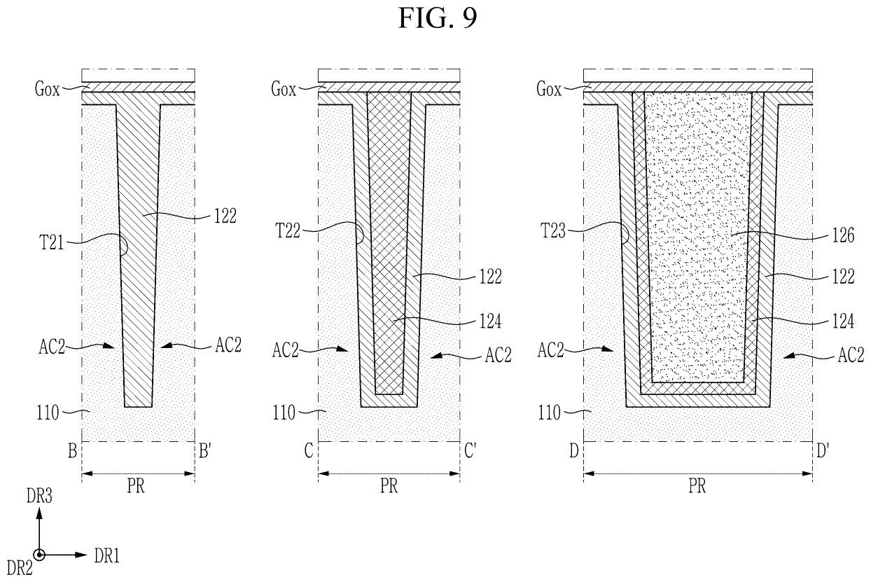

FIG. 8 and FIG. 9 each illustrate a cross-sectional view showing a semiconductor device according to a comparative embodiment. FIG. 8 illustrates a cross-sectional view taken along a line A-A′ of FIG. 2. FIG. 9 illustrates a cross-sectional view taken along lines B-B′, C-C′, and D-D′ of FIG. 3. FIG. 10 illustrates an enlarged view of a cross-section taken along a line D-D′ of FIG. 9. FIG. 10 illustrates a state in which some components of FIG. 9 have been removed in a subsequent process. Hereinafter, the comparative embodiment illustrated in FIGS. 8 to 10 will be described with a focus on differences from the embodiment illustrated in FIGS. 1 to 7.

Referring to FIG. 8, the first insulating layer 122, the second insulating layer 124, and the third insulating layer 126 may be positioned within the boundary trench T13. In the comparative embodiment, the fourth insulating layer 128 may not be positioned within the boundary trench T13.

The first insulating layer 122 may cover sidewalls and a bottom surface of the boundary trench T13. The first insulating layer 122 may cover a portion of a sidewall of the boundary trench T13. For example, the first insulating layer 122 may not cover an upper portion of the sidewall of the boundary trench T13 positioned in the cell region CR and other portions of the side wall adjacent thereto. An upper surface of an end portion of the first insulating layer 122 positioned in the cell region CR may be positioned at a lower level than an upper surface of the first active region AC1. The first insulating layer 122 may cover an upper surface of the second active region AC2. However, the invention is not limited thereto. For example, in some embodiments, the first insulating layer 122 may not cover the upper surface of the second active region AC2 (as illustrated in FIG. 10). The first insulating layer 122 may have a conformal shape along a profile of an inner surface of the boundary trench T13.

The second insulating layer 124 may be positioned on the first insulating layer 122. The second insulating layer 124 may cover an inner surface of the first insulating layer 122. The second insulating layer 124 may have a conformal shape along a profile of an inner surface of the first insulating layer 122. In the comparative example, the second insulating layer 124 may cover an entire inner surface of the first insulating layer 122 in the cell region CR and the peripheral circuit region PR. In the comparative example, the second insulating layer 124 may be protruded to a level higher than that of an upper surface of an end portion of the first insulating layer 122 in the cell region CR. In the cell region CR, an upper surface of an end portion of the second insulating layer 124 may be positioned at a higher level than that of an upper surface of an end portion of the first insulating layer 122. In the peripheral circuit region PR, an upper surface of an end portion of the second insulating layer 124 may be positioned at substantially the same level as that of the upper surface of the first insulating layer 122 covering the upper surface of the second active region AC2. The upper surface of the end portion of the second insulating layer 124 positioned in the cell region CR may be positioned at a lower level than that of the upper surface of the end portion of the second insulating layer 124 positioned in the peripheral circuit region PR.

The third insulating layer 126 may be positioned on the second insulating layer 124. The third insulating layer 126 may cover an inner surface of the second insulating layer 124. In the comparative embodiment, the third insulating layer 126 may cover a portion of an inner surface of the second insulating layer 124. The third insulating layer 126 may cover a portion of an inner surface of the second insulating layer 124 in the cell region CR, and may cover the entire inner surface of the second insulating layer 124 in the peripheral circuit region PR. The third insulating layer 126 may be surrounded by the second insulating layer 124.

The third insulating layer 126 may have a step between the cell region CR and the peripheral circuit region PR. An upper surface of the third insulating layer 126 positioned in the peripheral circuit region PR may be positioned at a higher level than that of an upper surface of the third insulating layer 126 positioned in the cell region CR. In the cell region CR, the upper surface of the third insulating layer 126 may be positioned at substantially the same level as that of the upper surface of the end portion of the first insulating layer 122. In the peripheral circuit region PR, the upper surface of the third insulating layer 126 may be positioned at substantially the same level as that of the upper surface of the first insulating layer 122 covering the upper surface of the second active region AC2.

In the comparative embodiment, an upper surface of the third insulating layer 126 positioned in the cell region CR may be positioned at a lower level than an upper surface of an end portion of the second insulating layer 124 positioned in the cell region CR. For example, in the cell region CR, an end portion of the second insulating layer 124 may protrude at a higher level than those of the upper surface of the end portion of the first insulating layer 122 and the upper surface of the third insulating layer 126.

The third insulating layer 126 may be separated from the first insulating layer 122 by the second insulating layer 124. The second insulating layer 124 may be positioned between the first insulating layer 122 and the third insulating layer 126.

In the comparative embodiment, the gate electrode WL may surround an upper portion of the second insulating layer 124 positioned in the cell region CR. The gate electrode WL may surround the upper portion of the second insulating layer 124 that protrudes beyond the upper surface of the end portion of the first insulating layer 122 and the upper surface of the third insulating layer 126 in the cell region CR. The gate electrode WL may cover upper and side surfaces of the protruding portion of the second insulating layer 124. The gate insulating layer Gox may be positioned between the upper and side surfaces of the protruding portion of the second insulating layer 124 and the gate electrode WL. The gate electrode WL may be separated from a surface of the second insulating layer 124 by the gate insulating layer Gox.

In comparative embodiment, a thickness of the gate electrode WL along the third direction DR3 within the boundary trench T13 may not be constant. As described above, in the comparative example, the upper portion of the second insulating layer 124 positioned in the cell region CR may protrude more than those of the upper surface of the end portion of the first insulating layer 122 and the upper surface of the third insulating layer 126. Accordingly, a thickness of the gate electrode WL positioned on the upper surface of the end portion of the second insulating layer 124 along the third direction DR3 may be thinner than a thickness of the gate electrode WL positioned on the upper surface of the end portion of the first insulating layer 122 and the upper surface of the third insulating layer 126 along the third direction DR3. For example, within the boundary trench T13, the lower surface of the gate electrode WL may have unevenness or irregularity. According to the comparative embodiment, there is a portion of the gate electrode WL with a thin thickness, so a problem of interruption in a flow of electric signals through the gate electrode WL may occur.

Referring to FIG. 9, the above-described first insulating layer 122 may be further positioned within the first peripheral circuit trench T21, the second peripheral circuit trench T22, and the third peripheral circuit trench T23. The above-described second insulating layer 124 may be further positioned within the second peripheral circuit trench T22 and the third peripheral circuit trench T23. The third insulating layer 126 described above may be further positioned within the third peripheral circuit trench T23. In the comparative embodiment, the fourth insulating layer 128 may not be positioned within the second peripheral circuit trench T22 and the third peripheral circuit trench T23.

A structure of the first insulating layer 122 may be substantially the same as that of the embodiment of FIG. 6, so a duplicate description will be omitted.

The second insulating layer 124 may be positioned on the first insulating layer 122 within the second peripheral circuit trench T22 and the third peripheral circuit trench T23. In the comparative embodiment, the second insulating layer 124 may cover the entire inner surface of the first insulating layer 122. In the comparative embodiment, the upper surface of the second insulating layer 124 may be positioned at substantially the same level as that of the upper surface of the first insulating layer 122 covering the upper surface of the second active region AC2.

The third insulating layer 126 may be positioned on the second insulating layer 124 within the third peripheral circuit trench T23. The third insulating layer 126 may cover an inner surface of the second insulating layer 124. The third insulating layer 126 may be in contact with the second insulating layer 124, and may be separated from the first insulating layer 122 by the second insulating layer 124. In the comparative embodiment, opposite sides of the third insulating layer 126 may be entirely covered by the second insulating layer 124. The upper surface of the third insulating layer 126 may be positioned at substantially the same level as that of the upper surface of the first insulating layer 122 covering the upper surface of the second active region AC2.

According to the comparative embodiment, the second insulating layer 124 may be positioned not only on lower portions but also on upper portions of the second peripheral circuit trench T22 and the third peripheral circuit trench T23. According to the comparative embodiment, the insulating layer 128 may not be positioned within the second peripheral circuit trench T22 and the third peripheral circuit trench T23. According to the comparative embodiment, the second insulating layer 124 may be positioned between the first insulating layer 122 and the third insulating layer 126, and the fourth insulating layer 128 may not be positioned.

For example, the second insulating layer 124 may include a silicon nitride, and the fourth insulating layer 128 may include a silicon oxide. Electrons may be trapped in a layer containing a silicon nitride.

According to the embodiment illustrated in FIG. 1 to FIG. 7, the second insulating layer 124 may be positioned on lower portions of the second peripheral circuit trench T22 and the third peripheral circuit trench T23, and the fourth insulating layer 128 may be positioned on an upper portion of the second peripheral circuit trench T22 and an upper portion of the third peripheral circuit trench T23. According to the embodiment, a region of the second insulating layer 124 within the second peripheral circuit trench T22 and the third peripheral circuit trench T23 may be smaller than that in the comparative example. Herein, the region of the second insulating layer 124 may indicate a length of the second insulating layer 124 along the third direction DR3. For example, silicon nitride (which is a material of the second insulating layer 124) may provide sites where electrons may be trapped. Therefore, as the amount of silicon nitride in the insulating layer TI decreases, the potential for issues caused by electron trapping is reduced. According to the embodiment illustrated in FIG. 1 to FIG. 7, a hot electron induced punch-through (HEIP) phenomenon may be reduced as a region where electrons are trapped is smaller than that in the comparative embodiment.

Referring back to the comparative embodiment, FIG. 10 illustrates a view for describing a shape of an upper surface of the insulating layer TI positioned within the third peripheral circuit trench T23 in detail. FIG. 10 illustrates a state in which a portion of the first insulating layer 122 and a portion of the gate insulating layer Gox of FIG. 9 are removed in a subsequent process. For example, in a subsequent process, the first insulating layer 122 and the gate insulating layer Gox positioned on an upper surface of the second active region AC2 may be removed. The removal process may be optionally performed (or omitted) after producing the structure described with reference to FIGS. 8 and 9. For example, FIG. 10 may illustrate a modified version of the semiconductor device, where the optional removal process is applied to the embodiment described with reference to FIGS. 8 and 9.

As described above, the second insulating layer 124 may include a material having a high etching selectivity for the first insulating layer 122 and the third insulating layer 126. For example, an etch-rate of the second insulating layer 124 may be significantly different from etch-rates of the first insulating layer 122 and the third insulating layer 126. For example, the etch-rate of the second insulating layer 124 may be slower than the etch-rates of the first insulating layer 122 and the third insulating layer 126.

Referring to FIG. 10, the upper surface of the end portion of the first insulating layer 122 and the upper surface of the third insulating layer 126 within the third peripheral circuit trench T23 may be positioned at a lower level than that of the upper surface of the end portion of the second insulating layer 124. The upper surface of the end portion of the first insulating layer 122 may have a gradient such that a height level thereof decreases as the upper surface of the end portion of the first insulating layer 122 moves toward a sidewall of the third peripheral circuit trench T23. In some embodiments, the upper surface of the end portion of the first insulating layer 122 may have a recessed shape toward a bottom surface of the third peripheral circuit trench T23 between the sidewall of the third peripheral circuit trench T23 and a side surface of the end portion of the second insulating layer 124. The upper surface of the third insulating layer 126 may have a recessed shape toward a bottom surface of the third peripheral circuit trench T23 between opposite ends of the second insulating layer 124.

According to the comparative embodiment, the upper surface of the end portion of the first insulating layer 122 may become higher as it approaches the upper surface of the second insulating layer 124. The upper surface of the third insulating layer 126 may become higher as it approaches the upper surface of the second insulating layer 124. According to the comparative embodiment, a portion extending from the upper surface of the end portion of the first insulating layer 122 to the upper surface of the second insulating layer 124 may be pointed. A portion extending from the upper surface of the second insulating layer 124 to the upper surface of the third insulating layer 126 may be pointed. For example, a width between a sidewall of the third peripheral circuit trench T23 and a side surface of the end portion of the second insulating layer 124 is thinner than a width between opposite end portions of the second insulating layer 124, so the upper surface of the end portion of the first insulating layer 122 may be recessed deeper than the upper surface of the third insulating layer 126. Accordingly, foreign substances (e.g., undesirable particles) FM caught between the sidewall of the third peripheral circuit trench T23 and the upper surface of the end portion of the first insulating layer 122 may not be removed properly. For example, the combination of the first insulating layer 122, the second insulating layer 124 and the third insulating layer 126 may have a composite upper surface. The composite upper surface may not have a gentle-curved shape. The composite upper surface may be an uneven surface such that the opposite end portions of the second insulating layer 124 protrude away from the bottom surface of the third peripheral circuit trench T23. Between the upper surface of the second insulating layer 124 and the sidewall of the third peripheral circuit trench T23, foreign substances (e.g., undesirable particles) FM may not be removed properly and remain.

Furthermore, when an additional gate electrode (e.g., gate electrode for transistors in the peripheral circuit region) is formed in a subsequent process, a thickness of the additional gate electrode along the third direction DR3 on the third peripheral circuit trench T23 may be thick on the upper surface of the end of the first insulating layer 122, thin on the upper surface of the end portion of the second insulating layer 124, and thick again on the upper surface of the third insulating layer 126. For example, a profile of the bottom surface of the additional gate electrode may be uneven.

According to the embodiment described with reference to FIGS. 1 to 7, the upper surface of the insulating layer TI positioned within the third peripheral circuit trench T23 may be a gently curved surface in which a boundary between the fourth insulating layer 128 and the first insulating layer 122 and a boundary between the fourth insulating layer 128 and the third insulating layer 126 are gently connected. Accordingly, foreign substances FM may be prevented from remaining between the sidewall of the third peripheral circuit trench T23 and the upper surface of the end portion of the first insulating layer 122. Furthermore, when an additional gate electrode is formed in a subsequent process, a thickness of the additional gate electrode along the third direction DR3 on the third peripheral circuit trench T23 may be more constant than that in the comparative example, and a profile of a lower surface of the additional gate electrode may be flatter (or smoother) than in the comparative example.

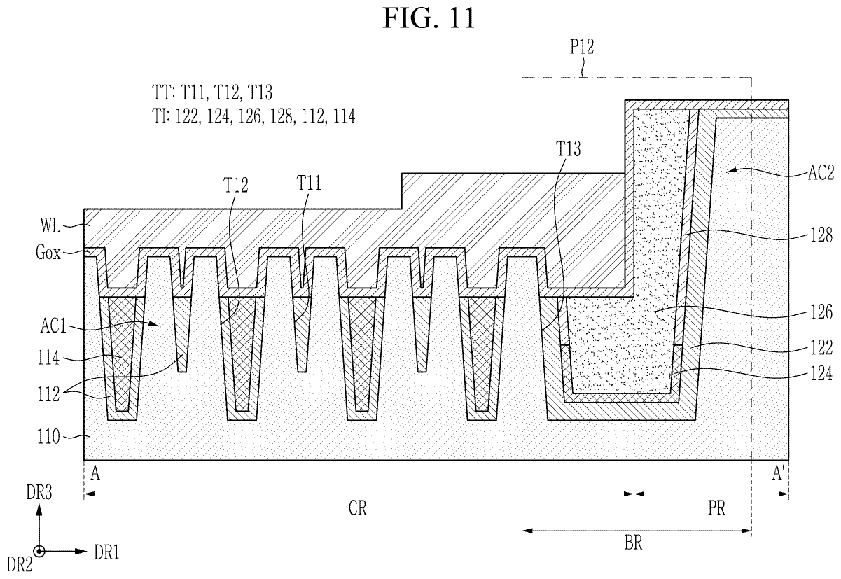

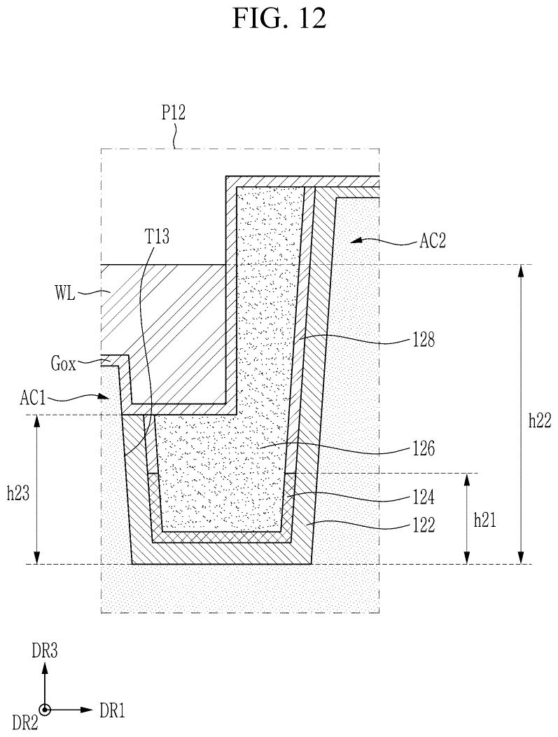

Hereinafter, a modified example of the semiconductor device according to the embodiment of FIGS. 1 to 7 will be described with reference to FIG. 11 and FIG. 12.

FIG. 11 illustrates a cross-sectional view of a semiconductor device according to an embodiment. FIG. 11 illustrates a cross-sectional view taken along a line A-A′ of FIG. 2. FIG. 12 illustrates an enlarged view of a region P12 in FIG. 11. The embodiment illustrated in FIGS. 11 and 12 may be substantially identical to the embodiment illustrated in FIGS. 1 to 7. In the embodiment illustrated in FIGS. 11 and 12, the same components as in the embodiments illustrated in FIGS. 1 to 7 may be referenced by the same symbols or numbers. The description of the embodiments illustrated with reference to FIGS. 1 to 7 may be applicable to the embodiment illustrated in FIGS. 11 and 12, unless context indicates otherwise.

Hereinafter, the embodiment illustrated in FIGS. 11 to 12 will be described with a focus on differences from the embodiment illustrated in FIGS. 1 to 7. The embodiment illustrated in FIGS. 11 and 12 may differ from the embodiment illustrated in FIGS. 1 to 7. In the embodiment, the fourth insulating layer 128 is further positioned on the upper surface of the end portion of the second insulating layer 124 positioned in the cell region CR within the boundary trench T13. For example, the height level of the end portion of the second insulating layer 124 within the boundary trench T13 in the embodiment illustrated in FIGS. 11 and 12 is relatively low as compared to the embodiment illustrated in FIGS. 1 to 7.

Referring to FIG. 11 and FIG. 12, the first insulating layer 122 may cover sidewalls and a bottom surface of the boundary trench T13. The first insulating layer 122 may cover a portion of a sidewall of the boundary trench T13. For example, the first insulating layer 122 may not cover an upper portion of the sidewall of the boundary trench T13 positioned in the cell region CR and other portions of the side wall adjacent thereto. An upper surface of an end portion of the first insulating layer 122 positioned in the cell region CR may be positioned at a lower level than an upper surface of the first active region AC1. The first insulating layer 122 may cover an upper surface of the second active region AC2. The first insulating layer 122 may have a conformal shape along a profile of an inner surface of the boundary trench T13.

The second insulating layer 124 may be positioned on the first insulating layer 122. The second insulating layer 124 may cover an inner surface of the first insulating layer 122. The second insulating layer 124 may have a conformal shape along a profile of an inner surface of the first insulating layer 122. In an embodiment, the second insulating layer 124 may cover a portion of the inner surface of the first insulating layer 122 in the cell region CR and the peripheral circuit region PR. In an embodiment, in the cell region CR, an upper surface of an end portion of the second insulating layer 124 may be positioned at a lower level than that of an upper surface of an end portion of the first insulating layer 122. The upper surface of the end portion of the second insulating layer 124 positioned in the peripheral circuit region PR may be positioned at substantially the same level as that of the upper surface of the end portion of the second insulating layer 124 positioned in the cell region CR.

The third insulating layer 126 may be positioned on the second insulating layer 124. The third insulating layer 126 may cover an inner surface of the second insulating layer 124. In an embodiment, the third insulating layer 126 may cover the entire inner surface of the second insulating layer 124. A lower portion of the third insulating layer 126 may be surrounded by the second insulating layer 124.

The third insulating layer 126 may have a step between the cell region CR and the peripheral circuit region PR. An upper surface of the third insulating layer 126 positioned in the peripheral circuit region PR may be positioned at a higher level than that of an upper surface of the third insulating layer 126 positioned in the cell region CR. In the cell region CR, the upper surface of the third insulating layer 126 may be positioned at substantially the same level as that of the upper surface of the end portion of the first insulating layer 122. In the peripheral circuit region PR, the upper surface of the third insulating layer 126 may be positioned at substantially the same level as that of the upper surface of the first insulating layer 122 covering the upper surface of the second active region AC2.

In an embodiment, in the cell region CR, an upper surface of the third insulating layer 126 may be positioned at a higher level than that of an upper surface of an end portion of the second insulating layer 124. For example, in the cell region CR, an end portion of the second insulating layer 124 may be recessed at a lower level than those of the upper surface of the end portion of the first insulating layer 122 and the upper surface of the third insulating layer 126. In the peripheral circuit region PR, the upper surface of the third insulating layer 126 may be positioned at a higher level than that of the upper surface of the end of the second insulating layer 124. For example, in the peripheral circuit region PR, an end portion of the second insulating layer 124 may be recessed at a lower level than those of the upper surface of the end portion of the first insulating layer 122 and the upper surface of the third insulating layer 126.

The third insulating layer 126 may be separated from the first insulating layer 122 by the second insulating layer 124. The second insulating layer 124 may be positioned between the first insulating layer 122 and the third insulating layer 126.

In the embodiment illustrated in FIGS. 11 and 12, unlike in the embodiments illustrated in FIGS. 1 to 7, the fourth insulating layer 128 may be further positioned between the first insulating layer 122 and the third insulating layer 126 not only in the peripheral circuit region PR but also in the cell region CR. The fourth insulating layer 128 may be positioned on the second insulating layer 124 between the first insulating layer 122 and the third insulating layer 126. The fourth insulating layer 128 may be positioned on an upper surface of an end portion of the second insulating layer 124. In an embodiment, in the cell region CR, the upper surface of the fourth insulating layer 128 may be positioned at substantially the same level as that of the upper surface of the end portion of the first insulating layer 122 and the upper surface of the third insulating layer 126. In the peripheral circuit region PR, the upper surface of the fourth insulating layer 128 may be positioned at substantially the same level as those of the upper surface of the third insulating layer 126 and the upper surface of the first insulating layer 122 covering the upper surface of the second active region AC2.

In an embodiment, the lower surface of the fourth insulating layer 128 in the cell region CR and the peripheral circuit region PR may be in contact with the upper surface of the end portion of the second insulating layer 124. The lower surface of the fourth insulating layer 128 may be referred to as a boundary surface between the fourth insulating layer 128 and the second insulating layer 124. The lower surface of the fourth insulating layer 128 may be positioned at a lower level than that of the upper surface of the gate electrode WL. As illustrated in FIG. 12, a height h21 from a bottom surface of the boundary trench T13 to a lower surface of the fourth insulating layer 128 may be lower than a height h22 from a bottom surface of the boundary trench T13 to an upper surface of the gate electrode WL.

In an embodiment, the lower surface of the fourth insulating layer 128 may be positioned at a lower level than those of the upper surface of the end portion of the first insulating layer 122 positioned in the cell region CR and the upper surface of the third insulating layer 126 positioned in the cell region CR. As illustrated in FIG. 12, the height h21 (in the peripheral circuit region PR) from the bottom surface of the boundary trench T13 to the lower surface of the fourth insulating layer 128 may be lower than the height h23 from the bottom surface of the boundary trench T13 to the upper surface of the end portion of the first insulating layer 122 positioned in the cell region CR.

In an embodiment, the gate electrode WL may cover the upper surface of the end portion of the first insulating layer 122 positioned in the cell region CR, the upper surface of the fourth insulating layer 128, the upper surface of the third insulating layer 126, and the side surface of the third insulating layer 126. In an embodiment, the fourth insulating layer 128 may be positioned between the lower surface of the gate electrode WL and the upper surface of the end portion of the second insulating layer 124 in the third direction DR3.

The gate insulating layer Gox may be positioned between the upper surface of the end portion of the first insulating layer 122 and the gate electrode WL, between the upper surface of the fourth insulating layer 128 and the gate electrode WL, between the upper surface of the third insulating layer 126 and the gate electrode WL, and between the side surface of the third insulating layer 126 and the gate electrode WL. The gate electrode WL may be spaced from the surfaces of the first insulating layer 122, the fourth insulating layer 128, and the third insulating layer 126 by the gate insulating layer Gox.

According to an embodiment, a thickness of the gate electrode WL along the third direction DR3 within the boundary trench T13 may be constant. As described above, in an embodiment, in the cell region CR, the upper surface of the fourth insulating layer 128 may be positioned at substantially the same level as that of the upper surface of the end portion of the first insulating layer 122 and the upper surface of the third insulating layer 126. Accordingly, a thickness of the gate electrode WL positioned on the upper surface of the fourth insulating layer 128 along the third direction DR3 may be the same as a thickness of the gate electrode WL positioned on the upper surface of the end portion of the first insulating layer 122 and the upper surface of the third insulating layer 126 along the third direction DR3. According to an embodiment, the thickness of the gate electrode WL within the boundary trench T13 is constantly greater than or equal to a predetermined thickness. For example, within the boundary trench T13, the lower surface of the gate electrode WL may be substantially at a consistent height level relative to the bottom surface of the boundary trench T13. For example, within the boundary trench T13, the lower surface of the gate electrode WL may be substantially smooth (for example, without any unevenness or irregularity). Accordingly, a problem of interruption of a flow of electric signals through the gate electrode WL may be prevented.

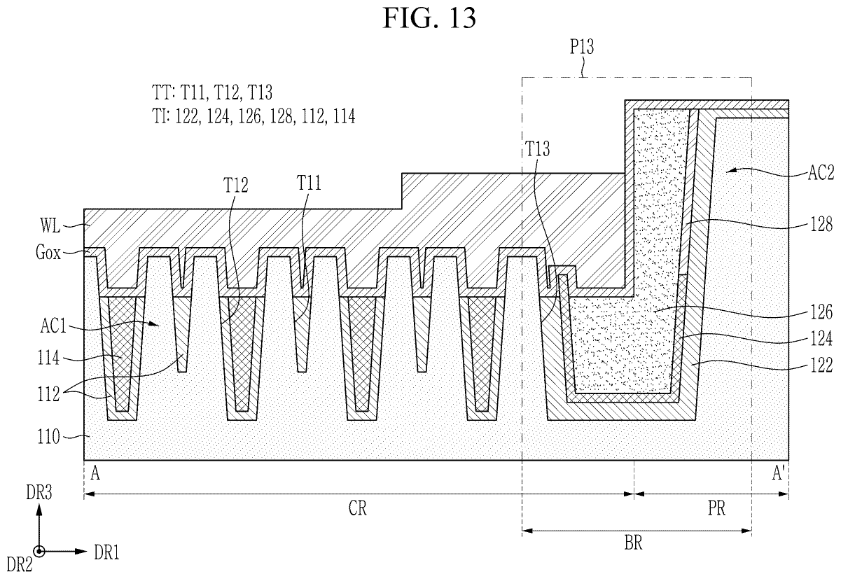

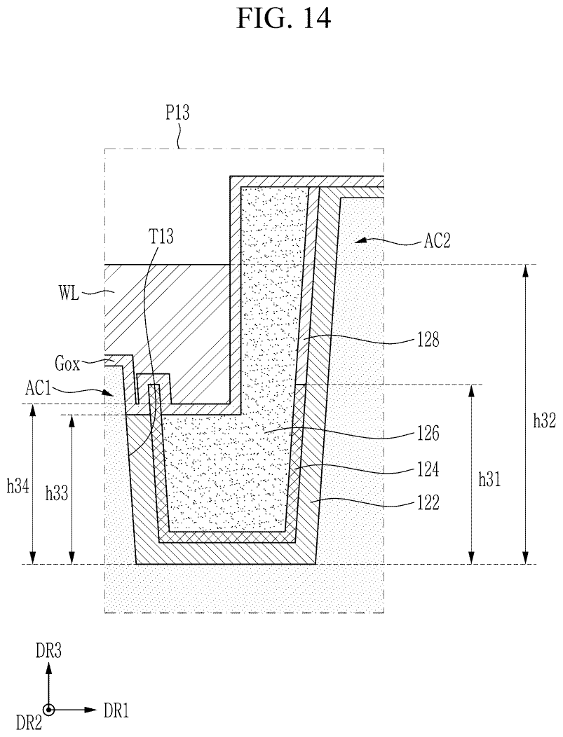

Hereinafter, a modified example of the semiconductor device according to the embodiment of FIGS. 1 to 7 will be described with reference to FIG. 13 and FIG. 14.

FIG. 13 illustrates a cross-sectional view of a semiconductor device according to an embodiment. FIG. 13 illustrates a cross-sectional view taken along a line A-A′ of FIG. 2. FIG. 14 illustrates an enlarged view of a region P13 in FIG. 13. The embodiment illustrated in FIGS. 13 and 14 may be substantially identical to the embodiment illustrated in FIGS. 1 to 7. In the embodiment illustrated in FIGS. 13 and 14, the same components as in the embodiments illustrated in FIGS. 1 to 7 may be referenced by the same symbols or numbers. The description of the embodiments illustrated with reference to FIGS. 1 to 7 may be applicable to the embodiment illustrated in FIGS. 11 and 12, unless context indicates otherwise. Hereinafter, the embodiment illustrated in FIGS. 13 to 14 will be described with a focus on differences from the embodiment illustrated in FIGS. 1 to 7. The embodiment illustrated in FIGS. 13 and 14 may differ from the embodiment illustrated in FIGS. 1 to 7. In the embodiment, the end portion of the second insulating layer 124 positioned in the cell region CR within the boundary trench T13 protrudes higher than the upper surface of the end portion of the first insulating layer 122 and the upper surface of the third insulating layer 126. For example, the height level of the end portion of the second insulating layer 124 within the boundary trench T13, as shown in the embodiment in FIGS. 13 and 14, is relatively higher than in the embodiment illustrated in FIGS. 1 to 7. The lower surface of the fourth insulating layer 128 may contact the upper surface of an end portion of the second insulating layer 124 in the boundary region BR. The other end portion of the second insulating layer 124 may protrude beyond the upper surface of the end portion of the first insulating layer 122, and may be surrounded by the gate insulating layer Gox and the gate electrode WL.

Referring to FIG. 13 and FIG. 14, the first insulating layer 122 may cover sidewalls and a bottom surface of the boundary trench T13. The first insulating layer 122 may cover a portion of a sidewall of the boundary trench T13. For example, the first insulating layer 122 may not cover an upper portion of the sidewall of the boundary trench T13 positioned in the cell region CR and other portions of the side wall adjacent thereto. An upper surface of an end portion of the first insulating layer 122 positioned in the cell region CR may be positioned at a lower level than an upper surface of the first active region AC1. The first insulating layer 122 may cover an upper surface of the second active region AC2. The first insulating layer 122 may have a conformal shape along a profile of an inner surface of the boundary trench T13.

The second insulating layer 124 may be positioned on the first insulating layer 122. The second insulating layer 124 may cover an inner surface of the first insulating layer 122. The second insulating layer 124 may have a conformal shape along a profile of an inner surface of the first insulating layer 122. In an embodiment, the second insulating layer 124 may cover the entire inner surface of the first insulating layer 122 in the cell region CR, and may cover a portion of the inner surface of the first insulating layer 122 in the peripheral circuit region PR. In an embodiment, in the cell region CR, an upper surface of an end portion of the second insulating layer 124 may be positioned at a higher level than that of the upper surface of the end portion of the first insulating layer 122. The upper surface of the end portion of the second insulating layer 124 positioned in the peripheral circuit region PR may be positioned at substantially the same level as that of the upper surface of the end portion of the second insulating layer 124 positioned in the cell region CR. In the peripheral circuit region PR, the upper surface of the end portion of the second insulating layer 124 may be positioned at a lower level than that of an upper surface of the second active area AC2.

The third insulating layer 126 may be positioned on the second insulating layer 124. The third insulating layer 126 may cover an inner surface of the second insulating layer 124. In an embodiment, the third insulating layer 126 may cover a portion of an inner surface of the second insulating layer 124 in the cell region CR, and may cover the entire inner surface of the second insulating layer 124 in the peripheral circuit region PR. A lower portion of the third insulating layer 126 may be surrounded by the second insulating layer 124.

The third insulating layer 126 may have a step between the cell region CR and the peripheral circuit region PR. An upper surface of the third insulating layer 126 positioned in the peripheral circuit region PR may be positioned at a higher level than that of an upper surface of the third insulating layer 126 positioned in the cell region CR. In the cell region CR, the upper surface of the third insulating layer 126 may be positioned at substantially the same level as that of the upper surface of the end portion of the first insulating layer 122. In the peripheral circuit region PR, the upper surface of the third insulating layer 126 may be positioned at substantially the same level as that of the upper surface of the first insulating layer 122 covering the upper surface of the second active region AC2.

In an embodiment, in the cell region CR, an upper surface of the third insulating layer 126 may be positioned at a lower level than that of an upper surface of an end portion of the second insulating layer 124. For example, in the cell region CR, an end portion of the second insulating layer 124 may protrude higher than the upper surface of the end portion of the first insulating layer 122 and the upper surface of the third insulating layer 126. In the peripheral circuit region PR, the upper surface of the third insulating layer 126 may be positioned at a higher level than that of the upper surface of the end of the second insulating layer 124. For example, in the peripheral circuit region PR, an end portion of the second insulating layer 124 may be recessed at a lower level than those of the upper surface of the end portion of the first insulating layer 122 and the upper surface of the third insulating layer 126.

The third insulating layer 126 may be separated from the first insulating layer 122 by the second insulating layer 124. The second insulating layer 124 may be positioned between the first insulating layer 122 and the third insulating layer 126.

In the peripheral circuit region PR, the fourth insulating layer 128 may be further positioned between the first insulating layer 122 and the third insulating layer 126. The fourth insulating layer 128 may be positioned on the second insulating layer 124 between the first insulating layer 122 and the third insulating layer 126. The fourth insulating layer 128 may be positioned on an upper surface of an end portion of the second insulating layer 124. In the peripheral circuit region PR, the upper surface of the fourth insulating layer 128 may be positioned at substantially the same level as those of the upper surface of the third insulating layer 126 and the upper surface of the first insulating layer 122 covering the upper surface of the second active region AC2.

The lower surface of the fourth insulating layer 128 in the peripheral circuit region PR may be in contact with the upper surface of the end portion of the second insulating layer 124. The lower surface of the fourth insulating layer 128 may be referred to as a boundary surface between the fourth insulating layer 128 and the second insulating layer 124. The lower surface of the fourth insulating layer 128 may be positioned at a lower level than that of the upper surface of the gate electrode WL. As illustrated in FIG. 14, a height h31 from a bottom surface of the boundary trench T13 to a lower surface of the fourth insulating layer 128 may be lower than a height h32 from a bottom surface of the boundary trench T13 to an upper surface of the gate electrode WL.

The lower surface of the fourth insulating layer 128 may be positioned at a lower level than those of the upper surface of the end portion of the first insulating layer 122 positioned in the cell region CR and the upper surface of the third insulating layer 126 positioned in the cell region CR. As illustrated in FIG. 14, the height h31 (in the peripheral circuit region PR) from the bottom surface of the boundary trench T13 to the lower surface of the fourth insulating layer 128 may be higher than the height h33 from the bottom surface of the boundary trench T13 to the upper surface of the end portion of the first insulating layer 122 positioned in the cell region CR.

In the embodiment illustrated in FIGS. 13 and 14, unlike in the embodiment illustrated in FIGS. 1 to 7, the lower surface of the fourth insulating layer 128 may be positioned at a higher level than that of the lower surface of the gate electrode WL. As illustrated in FIG. 14, a height h31 from a bottom surface of the boundary trench T13 to a lower surface of the fourth insulating layer 128 may be higher than a height h34 from a bottom surface of the boundary trench T13 to a lowermost surface of the gate electrode WL. The lowermost surface of the gate electrode WL may indicate a portion of the lower surface of the gate electrode WL that is closest to the bottom surface of the boundary trench T13.

In an embodiment, the gate electrode WL may surround an upper portion of the second insulating layer 124 positioned in the cell region CR. The gate electrode WL may surround the upper portion of the second insulating layer 124 that protrudes beyond the upper surface of the end portion of the first insulating layer 122 and the upper surface of the third insulating layer 126 in the cell region CR. In an embodiment, the gate electrode WL may cover the upper surface of the end position of the first insulating layer 122 positioned in the cell region CR, upper and side surfaces of the protruding portion of the second insulating layer 124, and upper and side surfaces of the third insulating layer 126.

The gate insulating layer Gox may be positioned between the upper surface of the end portion of the first insulating layer 122, between the upper and side surfaces of the protruding portion of the second insulating layer 124 and the gate electrode WL, and between the upper and side surfaces of the third insulating layer 126 and the gate electrode WL.

The gate electrode WL may be spaced from the surfaces of the first insulating layer 122, the second insulating layer 124, and the third insulating layer 126 by the gate insulating layer Gox.

According to an embodiment, a thickness of the gate electrode WL along the third direction DR3 within the boundary trench T13 may not be constant. As described above, in an embodiment, the upper surface of the end portion of the second insulating layer 124 positioned in the cell region CR may protrude more than those of the upper surface of the end portion of the first insulating layer 122 and the upper surface of the third insulating layer 126. For example, within the boundary trench T13, the lower surface of the gate electrode WL may have unevenness or irregularity. Accordingly, a thickness of the gate electrode WL positioned on the upper surface of the end portion of the second insulating layer 124 along the third direction DR3 may be thinner than a thickness of the gate electrode WL positioned on the upper surface of the end portion of the first insulating layer 122 and the upper surface of the third insulating layer 126 along the third direction DR3.

For example, in the embodiment illustrated in FIGS. 13 and 14, the upper surface of the end of the second insulating layer 124 may be positioned at a lower level than that of the upper surface of the first active region AC1. On the other hand, in the comparative embodiment illustrated in FIG. 8, the upper surface of the end portion of the second insulating layer 124 may be positioned at a higher level than that of the upper surface of the first active region AC1. A thickness of the gate electrode WL positioned on the upper surface of the end portion of the second insulating layer 124 according to an embodiment in the third direction DR3 may be thicker than a thickness of the gate electrode WL positioned on the upper surface of the end portion of the second insulating layer 124 according to the comparative embodiment illustrated in FIG. 8 in the third direction DR3. Accordingly, a minimum thickness of the gate electrode WL within the boundary trench T13 is greater than or equal to a predetermined thickness. For example, within the boundary trench T13, the gate electrode WL may have an average thickness greater than that in the comparative embodiment illustrated in FIG. 8. Accordingly, a problem of interruption of a flow of electric signals through the gate electrode WL may be prevented.

Referring to FIGS. 1 to 14 and related description, according to some embodiments, a semiconductor device may include a substrate 110 including a cell region CR and a peripheral circuit region PR, an insulating layer TI within an element separation trench TT defining active regions AC1 and AC2 of the substrate 110, a gate electrode WL crossing the active regions, and a gate insulating layer Gox disposed between the active regions and the gate electrode. The element separation trench TT may include a boundary trench part T13 positioned in a boundary region BR which is adjacent to boundaries of the cell region CR and the peripheral circuit region PR. In the boundary region, the insulating layer may include a first insulating part filling the boundary trench part, and a second insulating part which is surrounded by the first insulating part layer. For example, the first insulating part layer may surround first and second sidewalls of the second insulating part layer, and the first and second sidewalls may face away from each other.

The second insulating part may include a second insulating layer 124. The first insulating part may include a first insulating layer 122, a third insulating layer 126 and a fourth insulating layer 128. The second insulating part may have a nitrogen concentration greater than that of the first insulating part. The second insulating part may have a conformal shape along a profile of the boundary trench part. The second insulating part may have first and second end portions, which are positioned along opposite sidewalls of the boundary trench part, and the second end portion is positioned closer to a center of the cell region CR than the first end portion. At least one of upper surfaces of the first and second end portions is positioned at a lower level than upper surfaces of the active regions. The upper surfaces of both of the first and second end portions may be positioned at a lower level than the upper surfaces of the first active regions AC1. At least one of the upper surfaces of the first and second end portions may be positioned at a lower level than a lower surface of a portion of the gate electrode WL, and the portion of the gate electrode WL is positioned in the boundary region BR.

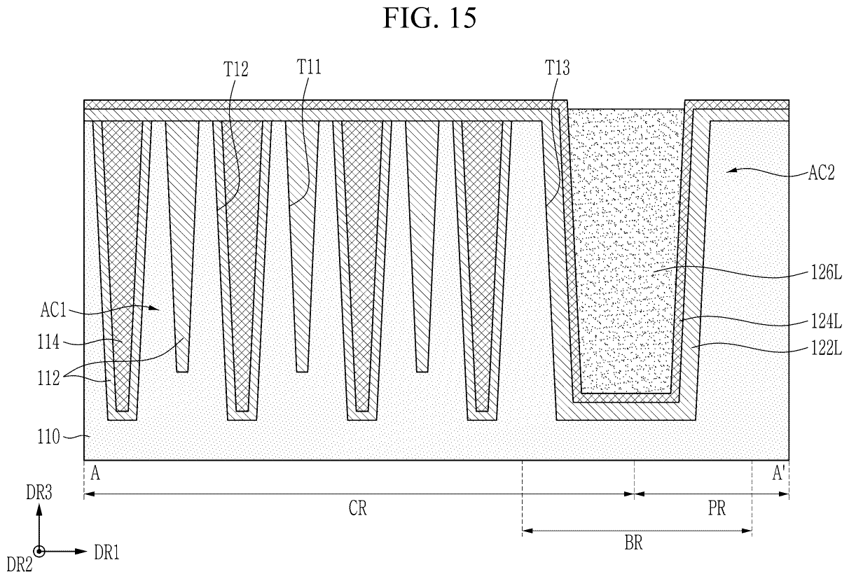

Hereinafter, a manufacturing method for the semiconductor device according to the embodiment illustrated in FIGS. 1 to 7 will be described with reference to FIG. 15 to FIG. 20.

FIG. 15 to FIG. 20 are cross-sectional views showing a manufacturing method of a semiconductor device according to an embodiment.

Referring to FIG. 15, a first insulating material layer 122L, a second insulating material layer 124L, and a third insulating material layer 126L may be sequentially positioned on the substrate 110.

The substrate 110 may include a cell region CR and a peripheral circuit region PR. The peripheral circuit region PR may surround the cell region CR in a plan view. The cell trench T11 and T12 may be positioned in the cell region CR, and the boundary trench T13 may be positioned between the cell region CR and the peripheral circuit region PR. For example, the boundary trench T13 may be positioned in a boundary region BR between the cell region CR and the peripheral circuit region PR. Although not shown, a peripheral circuit trench may be positioned in the peripheral circuit region PR. The first active region AC1 positioned in the cell region CR may be defined by the cell trenches T11 and T12, and the second active region AC2 positioned in the peripheral circuit region PR may be defined by peripheral circuit trenches. For example, the cell trench may be positioned between a plurality of first active regions AC1. Although not illustrated, the peripheral circuit trenches may be positioned between a plurality of second active regions AC2. The boundary trench T13 may be positioned between the first active region AC1 and the second active region AC2. The first active region AC1 and the second active region AC2 may collectively be an element separation trench. The second insulating material layer 124L may conformally cover a sidewall and a bottom surface of a boundary trench T13.

The cell trenches T11 and T12 may include a first cell trench T11 and a second cell trench T12 having a wider width than that of the first cell trench T11. The fifth insulating layer 112 may be positioned inside the first cell trench T11, and the fifth insulating layer 112 and the sixth insulating layer 114 may be positioned inside the second cell trench T12.

The fifth insulating layer 112 may cover sidewalls and bottom surfaces of the first cell trench T11 and the second cell trench T12. The fifth insulating layer 112 may fill an internal space of the first cell trench T11. The fifth insulating layer 112 may conformally cover the sidewalls and the bottom surface of the second cell trench T12.

The sixth insulating layer 114 may be positioned within the second cell trench T12, and may not be positioned within the first cell trench T11. Within the second cell trench T12, the sixth insulating layer 114 may be positioned on the fifth insulating layer 112. The sixth insulating layer 114 may cover an inner surface of the fifth insulating layer 112. The sixth insulating layer 114 may fill a space remaining after the fifth insulating layer 112 is formed within the second cell trench T12.

Each of the fifth insulating layer 112 and the sixth insulating layer 114 may include an insulating material. The sixth insulating layer 114 may include a material having an etch selectivity with respect to the fifth insulating layer 112. For example, the fifth insulating layer 112 may include a silicon oxide, and the sixth insulating layer 114 may include a silicon nitride. For example, in the semiconductor device, the nitrogen concentration of the sixth insulating layer may be greater than that of the fifth insulating layer.

According to an embodiment, the first insulating material layer 122L, the second insulating material layer 124L, and the third insulating material layer 126L covering sidewalls and a bottom surface of the boundary trench T13 may be sequentially formed. First, the first insulating material layer 122L may be deposited to conformally cover the side walls and the bottom surface of the boundary trench T13, and then the second insulating material layer 124L may be deposited to conformally cover the first insulating material layer 122L. The first insulating material layer 122L and the second insulating material layer 124L may be deposited, for example, through an atomic layer deposition (ALD) process, a chemical vapor deposition (CVD) process, or a physical vapor deposition (PVD) process, but the present invention is not limited thereto. The first insulating material layer 122L and the second insulating material layer 124L may fill a portion of a space (or a first space) within the boundary trench T13.

The first insulating material layer 122L and the second insulating material layer 124L may cover the upper surface of the first active region AC1. The first insulating material layer 122L and the second insulating material layer 124L may cover the upper surface of the fifth insulating layer 112 positioned within the first cell trench T11. The first insulating material layer 122L and the second insulating material layer 124L may cover an upper surface of an end portion of the fifth insulating layer 112 and an upper surface of the sixth insulating layer 114 positioned within the second cell trench T12.

Next, the third insulating material layer 126L may be deposited on the second insulating material layer 124L. The third insulating material layer 126L may be deposited through an atomic layer deposition (ALD) process, a chemical vapor deposition (CVD) process, or a physical vapor deposition (PVD) process, but the present invention is not limited thereto.

The third insulating material layer 126L may fill the remaining portion (or a second portion) of the space within the boundary trench T13. For example, the third insulating material layer 126L may fill the remaining space inside the boundary trench T13. The upper surface of the second insulating material layer 124L positioned outside the boundary trench T13 may be exposed. For example, the third insulating material layer 126L may be deposited to completely cover the upper surface of the second insulating material layer 124L, and then a portion of the third insulating material layer 126L may be removed to expose the upper surface of the second insulating material layer 124L positioned outside the boundary trench T13, but the present invention is not limited thereto.

Each of the first insulating material layer 122L, the second insulating material layer 124L, and the third insulating material layer 126L may include an insulating material. The third insulating material layer 126L may include an insulating material having a good gap-fill characteristic. The second insulating material layer 124L may include a material having a high etch selectivity with respect to the first insulating material layer 122L and the third insulating material layer 126L. According to an embodiment, the etching selectivity of the second insulating material layer 124L with respect to the first insulating material layer 122L and the third insulating material layer 126L may be higher than an etching selectivity of the fourth insulating material layer 128L with respect to the first insulating material layer 122L and the third insulating material layer 126L, as described later. For example, the first insulating material layer 122L may include a silicon oxide, the second insulating material layer 124L may include a silicon nitride, and the third insulating material layer 126L may include tonene silazene (TOSZ), but the present invention is not limited thereto.

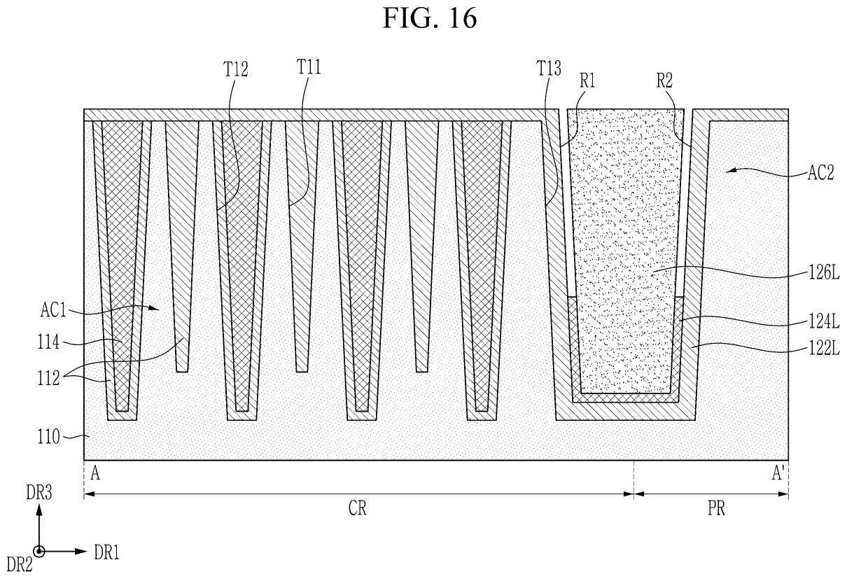

Referring to FIG. 16, a recess may be formed by partially removing the second insulating material layer 124L. The recess may have sides exposing the first insulating material layer 122L and the third insulating material layer 126L and a bottom exposing the second insulating material layer 124L. For example, a portion of the second insulating material layer 124L may be etched to form recesses R1 and R2 having (or defined by) the first insulating material layer 122L and the third insulating material layer 126L as sidewalls and the second insulating material layer 124L as a bottom surface.

For example, the etching process may be performed using an etchant having a high etching selectivity of the second insulating material layer 124L with respect to the first insulating material layer 122L and the third insulating material layer 126L. In an embodiment, the etching process may be performed using an etchant having a higher etch-rate of the second insulating material layer 124L than those of the first insulating material layer 122L and the third insulating material layer 126L. For example, the etchant may remove a greater amount of material from the second insulating material layer 124L than from the first insulating material layer 122L or the third insulating material layer 126L during a predetermined time. In this case, the second insulating material layer 124L may be etched, and the first insulating material layer 122L and the third insulating material layer 126L may be hardly etched. Accordingly, the recesses R1 and R2 may be formed such that each of the recesses R1 and R2 faces the first insulating material layer 122L and the third insulating material layer 126L as sidewalls and the upper surface of the end portion of the second insulating material layer 124L as the bottom surface. Additionally, the upper surface of the first insulating material layer 122L and the upper surface of the third insulating material layer 126L may be exposed. For example, in the semiconductor device, the nitrogen concentration of the second insulating material layer may be greater than that of the first and third insulating material layers.

The recesses R1 and R2 may include a first recess R1 positioned in the cell region CR and a second recess R2 positioned in the peripheral circuit region PR. Depths of the first recess R1 and the second recess R2 may be substantially the same. For example, an upper surface of an end portion of the second insulating material layer 124L positioned in the cell region CR and an upper surface of an end portion of the second insulating material layer 124L positioned in the peripheral circuit region PR may be positioned at substantially the same level.

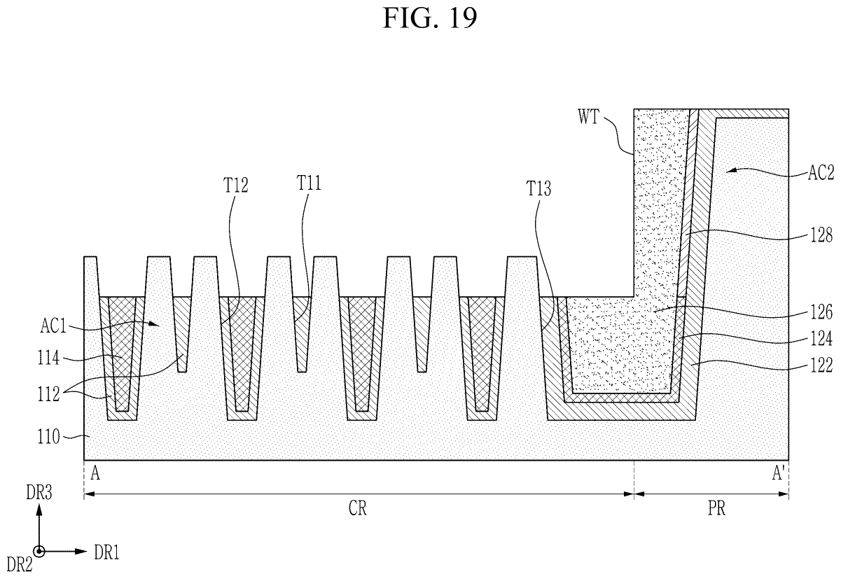

In FIG. 16, a height of the upper surface of the end portion of the second insulating material layer 124L within the boundary trench T13 may vary depending on the depths of the recesses R1 and R2, and a height (or amount) of the fourth insulating material layer 128L filled within the recesses R1 and R2 may vary by a subsequent process. For example, the recesses R1 and R2 may be formed deeper than those illustrated in FIG. 16 such that, when a gate trench WT (FIG. 19) is formed (after the fourth insulating material layer 128L is filled in the recesses R1 and R2 in subsequent processes), a portion of the fourth insulating material layer 128L positioned in the cell region CR may remain (be removed, not completely). In this case, as described in the embodiment illustrated in FIG. 11 and FIG. 12, the fourth insulating layer 128 may be further positioned on the upper surface of the end portion of the second insulating layer 124 positioned in the cell region CR, and opposite sides of the fourth insulating layer 128 may be covered by the first insulating layer 122 and the third insulating layer 126.

As another example, the recesses R1 and R2 may be formed shallower than those illustrated in FIG. 16 such that, when the gate trench WT (FIG. 19) is formed (after the fourth insulating material layer 128L is filled in the recesses R1 and R2 in subsequent processes), the fourth insulating material layer 128L positioned in the cell region CR may be completely removed, and the end portion of the second insulating material layer 124L may be exposed. For example, as described in the embodiment illustrated in FIG. 13 and FIG. 14, the end portion of the second insulating layer 124 positioned in the cell region CR may protrude higher than the upper surface of the end portion of the first insulating material layer 122L positioned in the cell region CR and the upper surface of the third insulating material layer 126L. The upper surface of the end portion of the second insulating material layer 124L may be positioned at a higher level than those of the upper surface of the end portion of the first insulating material layer 122L positioned in the cell region CR and the upper surface of the third insulating material layer 126L.

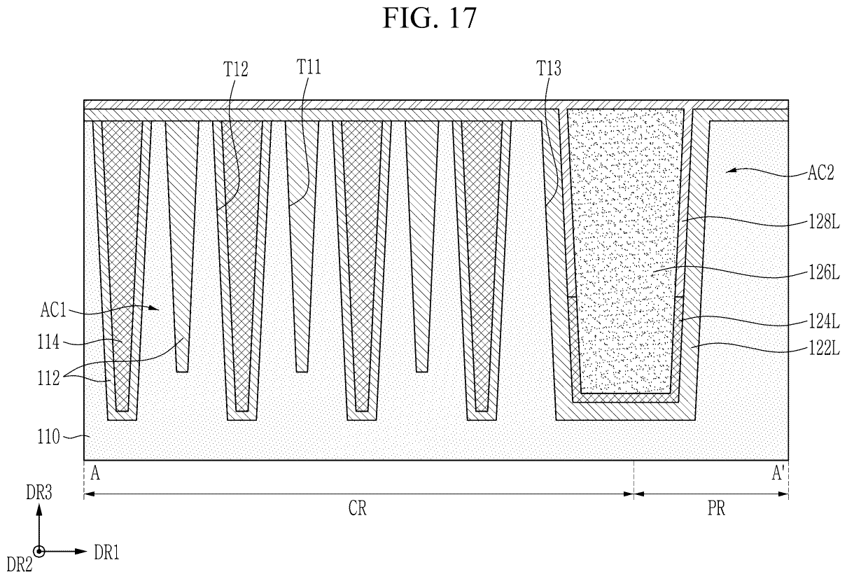

Referring to FIG. 17, the fourth insulating material layer 128L may be formed to fill the recesses R1 and R2 of FIG. 16. The fourth insulating material layer 128L may be deposited through an atomic layer deposition (ALD) process, a chemical vapor deposition (CVD) process, or a physical vapor deposition (PVD) process, for example, but the present invention is not limited thereto.

The fourth insulating material layer 128L may fill spaces inside the recesses R1 and R2. The fourth insulating material layer 128L may cover the upper surface of the first insulating material layer 122L and the upper surface of the third insulating material layer 126L positioned outside the boundary trench T13.

The fourth insulating material layer 128L may include an insulating material. The fourth insulating material layer 128L may include a material having a low etch selectivity with respect to the first insulating material layer 122L and the third insulating material layer 126L. According to an embodiment, the etch selectivity of the fourth insulating material layer 128L with respect to the first insulating material layer 122L and the third insulating material layer 126L may be lower than the etch selectivity of the second insulating material layer 124L with respect to the first insulating material layer 122L and the third insulating material layer 126L. For example, the fourth insulating material layer 128L may include the same material as that of the first insulating material layer 122L or the third insulating material layer 126L. For example, the fourth insulating material layer 128L may include a silicon oxide. For example, in the semiconductor device, the nitrogen concentration of the second insulating material layer may be greater than that of the first, third and fourth insulating material layers.

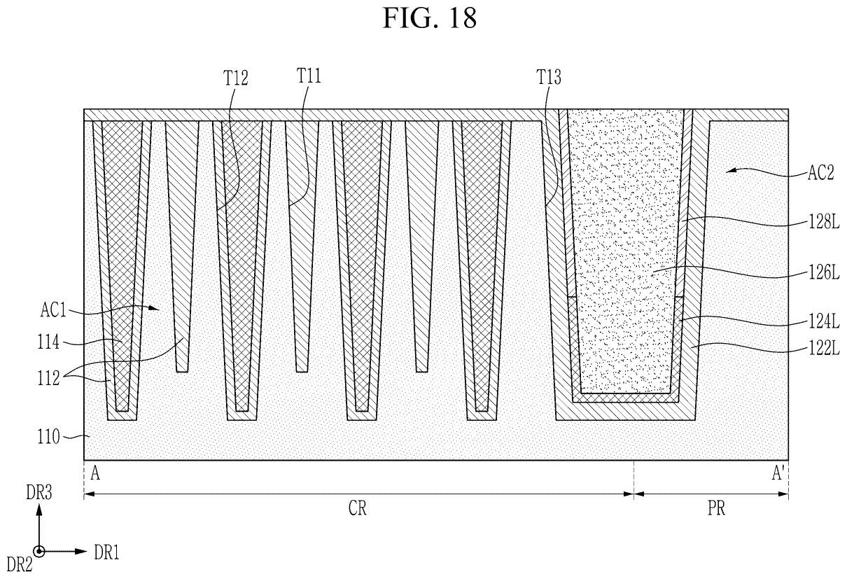

Referring to FIG. 18, a portion of the fourth insulating material layer 128L may be removed to expose the upper surface of the first insulating material layer 122L and the upper surface of the third insulating material layer 126L positioned outside the boundary trench T13.

For example, portions of the fourth insulating material layer 128L covering the upper surface of the first insulating material layer 122L positioned outside the boundary trench T13 and the upper surface of the third insulating material layer 126L may be removed through an etch-back or chemical mechanical polishing (CMP) process. The process of removing a portion of the fourth insulating material layer 128L is not limited to the process described above.

Referring to FIG. 19, the gate trench WT may be formed to extend in the first direction DR1 across the first active region AC1 of the cell region CR. The gate trench WT may extend to a boundary between the cell region CR and the peripheral circuit region PR. The gate trench WT may be formed by dry etching, for example, but the present invention is not limited thereto.

For example, an etching process may be performed using an etchant having a lower etching selectivity of the fourth insulating material layer 128L with respect to the first insulating material layer 122L and the third insulating material layer 126L than an etching selectivity of the second insulating material layer 124L with respect to the first insulating material layer 122L and the third insulating material layer 126L. For example, the etching process may be performed on the cell region CR. The peripheral circuit region PR may be covered with a mask during the etching process.

Accordingly, at least a portion of the first insulating material layer 122L, a portion of the third insulating material layer 126L, and a portion of the fourth insulating material layer 128L positioned in the cell region CR within the boundary trench T13 may be etched and removed. The first insulating material layer 122L, the second insulating material layer 124L, the third insulating material layer 126L, and the fourth insulating material layer 128L that remain without being removed within the boundary trench T13 may become the first insulating layer 122, the second insulating layer 124, the third insulating layer 126, and the fourth insulating layer 128, respectively. The third insulating layer 126 may have a step at a boundary between the cell region CR and the peripheral circuit region PR. An upper surface of the third insulating layer 126 positioned in the peripheral circuit region PR may be positioned at a higher level than that of an upper surface of the third insulating layer 126 positioned in the cell region CR.

In FIG. 19, the entire fourth insulating material layer 128L positioned in the cell region CR is shown to have been removed, but the present invention is not limited thereto. For example, depending on a depth of the gate trench WT, a portion of the fourth insulating material layer 128L positioned in the cell region CR may be removed. In this case, as described in the embodiment illustrated in FIG. 11 and FIG. 12, the fourth insulating layer 128 may be further positioned on the upper surface of the end portion of the second insulating layer 124 positioned in the cell region CR, and opposite sides of the fourth insulating layer 128 may be covered by the first insulating layer 122 and the third insulating layer 126.

Furthermore, in FIG. 19, the upper surface of the end portion of the second insulating layer 124 positioned in the cell region CR is illustrated as being positioned at substantially the same level as those of the upper surface of the end portion of the first insulating layer 122 positioned in the cell region CR and the upper surface of the third insulating layer 126, but the present invention is not limited thereto. For example, due to the etching selectivity of the second insulating material layer 124L with respect to the first insulating material layer 122L and the third insulating material layer 126L, the first insulating material layer 122L and the third insulating material layer 126L may be etched more than the second insulating material layer 124L. In this case, as described in the embodiments illustrated in FIGS. 13 and 14, the upper surface of the end portion of the second insulating layer 124 positioned in the cell region CR may be positioned at a higher level than those of the upper surface of the end portion of the first insulating layer 122 positioned in the cell region CR and the upper surface of the third insulating layer 126, and the end portion of the second insulating layer 124 positioned in the cell region CR may protrude higher than the upper surface of the end portion of the first insulating layer 122 and the upper surface of the third insulating layer 126.

Furthermore, a portion of the fifth insulating layer 112 and a portion of the sixth insulating layer 114 may be etched and removed within the first cell trench T11 and the second cell trench T12. A portion of the first active region AC1 may also be etched and removed. For example, for an etchant used in an etching process, etch-rates of materials of the fifth insulating layer 112 and the sixth insulating layer 114 may be faster than an etch-rate of a material of the first active region AC1. Accordingly, the first active region AC1 may have a fin shape in which an upper portion of the first active region AC1 protrudes higher than upper surfaces of the fifth insulating layer 112 and the sixth insulating layer 114.

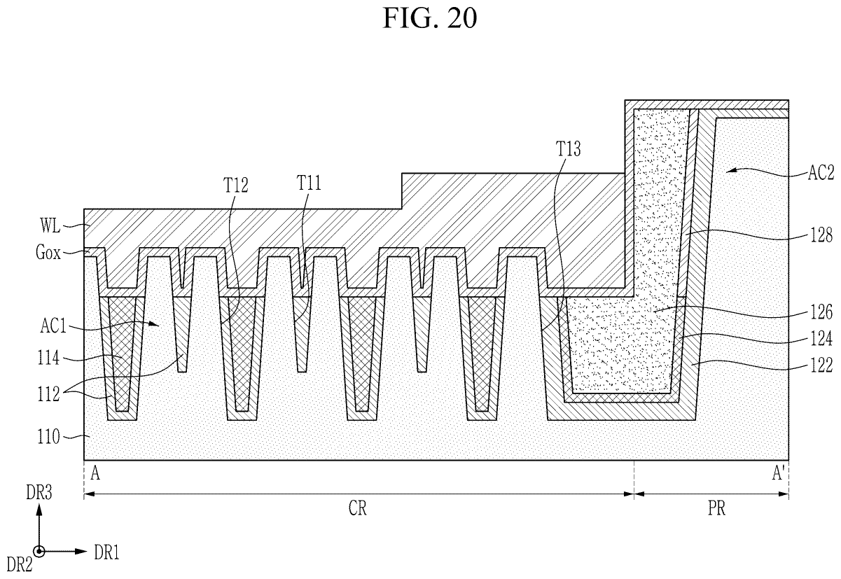

By referring to FIG. 20, the gate insulating layer Gox and the gate electrode WL may be formed. The gate insulating layer Gox may be formed to conformally cover the sidewalls and the bottom surface of the gate trench WT of FIG. 19. The gate insulating layer Gox may be formed through an ALD, CVD, or PVD process, for example, the present invention is not limited thereto.

The gate insulating layer Gox may cover the upper surface of the first active region AC1. The gate insulating layer Gox may cover an upper portion of the sidewall of the first cell trench T11. The gate insulating layer Gox may cover an upper surface of the fifth insulating layer 112 positioned within the first cell trench T11. The gate insulating layer Gox may cover an upper portion of the sidewall of the second cell trench T12. The gate insulating layer Gox may cover an upper surface of an end portion of the fifth insulating layer 112 positioned within the second cell trench T12 and an upper surface of the sixth insulating layer 114 positioned within the second cell trench T12.

The gate insulating layer Gox may cover an upper portion of the sidewall of the boundary trench T13 positioned in the cell region CR. The gate insulating layer Gox may cover an upper surface of an end portion of the first insulating layer 122, an upper surface of an end portion of the second insulating layer 124, and an upper surface of the third insulating layer 126 positioned in the cell region CR within the boundary trench T13. The gate insulating layer Gox may cover a side surface of the third insulating layer 126 positioned at a boundary between the cell region CR and the peripheral circuit region PR within the boundary trench T13.

The gate insulating layer Gox may cover an upper surface of the third insulating layer 126, an upper surface of the fourth insulating layer 128, and an upper surface of the first insulating layer 122 in the peripheral circuit region PR. The gate electrode may partially cover the first to fourth insulating material layers within the above boundary trench T13.

The gate electrode WL may be formed within the gate trench WT of FIG. 19. The gate electrode WL may be positioned on the gate insulating layer Gox. The gate electrode WL may be formed through an ALD, CVD, or PVD process, for example, the present invention is not limited thereto.

The gate electrode WL may extend in the first direction DR1 across the first active region AC1. The gate electrode WL may extend to a boundary between the cell region CR and the peripheral circuit region PR. For example, the gate electrode WL may be positioned in the cell region CR, and may not be positioned in the peripheral circuit region PR.

The gate electrode WL may surround the upper portion of the first active region AC1. The gate electrode WL may cover an upper surface of the fifth insulating layer 112 positioned within the first cell trench T11. The gate electrode WL may cover an upper surface of an end portion of the fifth insulating layer 112 and an upper surface of the sixth insulating layer 114 positioned within the second cell trench T12. The gate electrode WL may cover the upper surface of the end portion of the first insulating layer 122, the upper surface of the end of the second insulating layer 124, and the upper and side surfaces of the third insulating layer 126 positioned within the boundary trench T13.

According to an embodiment, a thickness of a portion of the gate electrode WL adjacent to the peripheral circuit region PR along the third direction DR3 may be thicker than a thickness of another portion of the gate electrode WL along the third direction DR3. A thickness of the gate electrode WL along the third direction DR3 within the boundary trench T13 may be constant. A lower surface of the gate electrode WL within the boundary trench T13 may be substantially flat.

According to an embodiment, a lower surface of the fourth insulating layer 128 positioned in the peripheral circuit region PR within the boundary trench T13 may be positioned at a lower level than that of the upper surface of the gate electrode WL. A lower surface of the fourth insulating layer 128 may be in contact with the upper surface of the second insulating layer 124. A boundary between the fourth insulating layer 128 and the second insulating layer 124 may be positioned at a level lower than that of the upper surface of the gate electrode WL.

Subsequently, a portion of the first insulating layer 122 and a portion of the gate insulating layer Gox may be removed. For example, the first insulating layer 122 and the gate insulating layer Gox positioned on an upper surface of the second active region may be removed. The removal process may be optionally performed.

FIG. 15 to FIG. 20 illustrate a part of a process for forming a semiconductor device. The semiconductor device illustrated in FIGS. 15 to 20 are illustrated with a focus on a process of forming an element separation structure, and the semiconductor device may have some of the components illustrated in FIG. 20 changed or may further include other components through subsequent processes. For example, bit lines, capacitors, etc. may be further included in the semiconductor device.

While the invention is described with embodiments above, it is to be understood that the invention is not limited to the disclosed embodiments, but, on the contrary, is intended to cover various modifications and equivalent dispositions included within the spirit and scope of the appended claims.

What is claimed is:

1. A semiconductor device comprising:
a substrate including a cell region and a peripheral circuit region;
an insulating layer within an element separation trench defining active regions of the substrate;
a gate electrode crossing the active regions; and
a gate insulating layer between the active regions and the gate electrode,
wherein the element separation trench includes a boundary trench part positioned in a boundary region which is adjacent to boundaries of the cell region and the peripheral circuit region,
wherein the insulating layer includes:
a first insulating layer covering sidewalls and a bottom surface of the boundary trench part,
a second insulating layer formed on the first insulating layer and covering a portion of an inner surface of the first insulating layer in the boundary trench part,
a third insulating layer formed on the second insulating layer and covering a first inner surface of the second insulating layer, and
a fourth insulating layer on an upper surface of a first end portion of the second insulating layer,
wherein the second insulating layer is positioned between the first insulating layer and the third insulating layer, and
wherein, in the boundary region, a lower surface of the fourth insulating layer is positioned at a level lower than that of an upper surface of the gate electrode.

2. The semiconductor device of claim 1, wherein a portion of an upper surface of an end portion of the first insulating layer, the upper surface of the first end portion of the second insulating layer, and a portion of an upper surface of the third insulating layer is positioned at a lower level than that of upper surfaces of the active regions.

3. The semiconductor device of claim 2, wherein:
in the boundary region, the upper surface of the first end portion of the second insulating layer and an upper surface of a second end portion of the second insulating layer are positioned at the same level, and
the second end portion of the second insulating layer is positioned closer to a center of the cell region than the first end portion of the second insulating layer.

4. The semiconductor device of claim 1, wherein
a portion of the gate electrode adjacent to the peripheral circuit region is thicker than another portion of the gate electrode in a direction perpendicular to a surface of the substrate.

5. The semiconductor device of claim 1, wherein
in the boundary region, the lower surface of the fourth insulating layer is positioned at a lower level than that of a lower surface of the gate electrode.

6. The semiconductor device of claim 5, wherein:
in the boundary region, an upper surface of a second end portion of the second insulating layer is positioned at the same level as or a lower level than those of an upper surface of a first end portion of the first insulating layer and a first portion of an upper surface of the third insulating layer, and
the second end portion of the second insulating layer is positioned closer to a center of the cell region than the first end portion of the second insulating layer.

7. The semiconductor device of claim 6, wherein:
in the boundary region, the fourth insulating layer is further positioned on the second end portion of the second insulating layer, and
a portion of an upper surface of the fourth insulating layer is positioned at the same level as the upper surface of the first end portion of the first insulating layer and the first portion of the upper surface of the third insulating layer.

8. The semiconductor device of claim 5, wherein:
a thickness of a portion of the gate electrode in a direction perpendicular to a surface of the substrate is constant, and
the portion of the gate electrode is positioned on a sidewall and an upper surface of the third insulating layer.

9. The semiconductor device of claim 1, wherein
the lower surface of the fourth insulating layer in the boundary region is positioned at a higher level than a lowermost surface of the gate electrode.

10. The semiconductor device of claim 9, wherein
an upper portion of an end portion of the second insulating layer in the boundary region is surrounded by the gate electrode.

11. The semiconductor device of claim 1, wherein
the element separation trench includes a peripheral circuit trench part positioned in the peripheral circuit region,
the peripheral circuit trench part includes:
a first peripheral circuit trench part having a first width,
a second peripheral circuit trench part having a second width that is greater than the first width, and
a third peripheral circuit trench part having a third width that is greater than the second width,
the first insulating layer is further within the first peripheral circuit trench part, the second peripheral circuit trench part, and the third peripheral circuit trench part,
the second insulating layer is further positioned within the second peripheral circuit trench part and the third peripheral circuit trench part,
the third insulating layer is further positioned within the third peripheral circuit trench part, and
the fourth insulating layer is further positioned within the second peripheral circuit trench part and the third peripheral circuit trench part.

12. The semiconductor device of claim 11, wherein, within the second peripheral circuit trench part:
the first insulating layer covers a sidewall and a bottom surface of the second peripheral circuit trench part,
side and lower surfaces of the second insulating layer are surrounded by the first insulating layer, and
the fourth insulating layer is on an upper surface of the second insulating layer.

13. The semiconductor device of claim 11, wherein, within the third peripheral circuit trench part:
the first insulating layer covers a sidewall and a bottom surface of the third peripheral circuit trench part,
an outer surface of the second insulating layer is surrounded by the first insulating layer,
the third insulating layer covers a second inner surface of the second insulating layer, and
the fourth insulating layer is on an upper surface of an end portion of the second insulating layer between the first insulating layer and the third insulating layer.

14. The semiconductor device of claim 13, wherein, within the third peripheral circuit trench part:
the combination of the first insulating layer, the third insulating layer and the fourth insulating layer has a composite upper surface, and
the composite upper surface has a recessed shape such that a height level of the composite upper surface decreases as the composite upper surface moves away from edges of the composite upper surface.

15. The semiconductor device of claim 1, wherein
an etching selectivity of the fourth insulating layer with respect to the first insulating layer and the third insulating layer is lower than an etching selectivity of the second insulating layer with respect to the first insulating layer and the third insulating layer.

16. A semiconductor device comprising:
a substrate including a cell region and a peripheral circuit region;
an insulating layer within an element separation trench defining active regions of the substrate;
a gate electrode crossing the active regions; and
a gate insulating layer between the active regions and the gate electrode,
wherein the element separation trench includes a boundary trench part positioned at a boundary between the cell region and the peripheral circuit region,
wherein the insulating layer positioned within the boundary trench part includes:
a first insulating layer covering sidewalls and a bottom surface of the boundary trench part,
a second insulating layer on the first insulating layer and covering a portion of an inner surface of the first insulating layer in the peripheral circuit region,
a third insulating layer on the second insulating layer and covering an inner surface of the second insulating layer, and
a fourth insulating layer on an upper surface of an end portion of the second insulating layer,
wherein the second insulating layer is positioned between the first insulating layer and the third insulating layer in the peripheral circuit region, and
wherein a boundary surface between the fourth insulating layer and the second insulating layer is positioned at a lower level than an upper surface of the gate electrode.

17. The semiconductor device of claim 16, wherein:
a lower surface of the fourth insulating layer is positioned at a lower level than that of a lower surface of the gate electrode, and
an upper surface of the second insulating layer in the cell region is positioned at the same level as or a lower level than those of an upper surface of the first insulating layer and an upper surface of the third insulating layer.

18. The semiconductor device of claim 16, wherein:
a lower surface of the fourth insulating layer is positioned at a higher level than that of a lower surface of the gate electrode, and
an upper portion of the second insulating layer in the cell region is surrounded by the gate electrode.

19. A semiconductor device comprising:
a substrate including a cell region and a peripheral circuit region;
an insulating layer within an element separation trench defining active regions of the substrate;
a gate electrode crossing the active regions; and
a gate insulating layer between the active regions and the gate electrode,
wherein the element separation trench includes a boundary trench part positioned in a boundary region which is adjacent to boundaries of the cell region and the peripheral circuit region,
wherein, in the boundary region, the insulating layer includes:
a first insulating part filling the boundary trench part, and
a second insulating part surrounded by the first insulating part,
wherein the second insulating part:
has a nitrogen concentration greater than that of the first insulating part,
has a conformal shape along a profile of the boundary trench part,
has first and second end portions, which are positioned along opposite sidewalls of the boundary trench part, and the second end portion is positioned closer to a center of the cell region than the first end portion,
wherein upper surfaces of both of the first and second end portions are positioned at a lower level than upper surfaces of the active regions.

20. The semiconductor device of claim 19, wherein the upper surfaces of both of the first and second end portions are positioned at a lower level than a lower surface of a portion of the gate electrode, and the portion of the gate electrode is positioned in the boundary region.
